(19) United States
(12) Patent Application Publication
(10) Pub. No.: US 2002/0180048 A1
(43) Pub. Date: Dec. 5, 2002

(54) Stacked device and method of fabricating same

(75) Inventors: James Irwin, Paige, TX (US); Timothy Joe Johnson, Mundelein, IL (US)

Correspondence Address: OBLON SPIVAK MCCLELLAND MAIER & NEUSTADT PC, FOURTH FLOOR, 1755 JEFFERSON DAVIS HIGHWAY, ARLINGTON, VA, 22202, US

(73) Assignee: MOTOROLA, INC., Schuamburg, IL

(21) Appl. No.: 09/865,448

(22) Filed: May 29, 2001

(51) Int. Cl. H01L 23/48; H01L 23/52; H01L 29/40

(52) U.S. Cl. 257/758

(57) ABSTRACT

A stacked semiconductor device structure includes an underlying MOS device formed on a silicon substrate and an overlying GaAs device. An accommodating buffer layer is formed between the MOS device and the GaAs device. The accommodating buffer layer is a layer of monocrystalline oxide spaced apart from the silicon substrate by an amorphous interface layer of silicon oxide, and is lattice matched to both the underlying silicon substrate and the overlying GaAs layer. Any lattice mismatch between the accommodating buffer layer and the underlying silicon substrate is taken care of by the amorphous interface layer. Metal interconnects are provided for connecting the MOS device and the GaAs device.

### BACKGROUND OF THE INVENTION

1. Field of the Invention

The present invention relates generally to semiconductor structures and devices and to a method for their fabrication, and more specifically to a stacked GaAs and Si Field Effect Transistor (FET) and to the fabrication and use of a stacked GaAs and Si FET.

2. Description of the Related Art

One of the many demands of cellular systems is for more powerful transistors. Power transistors for RF and microwave applications generally fall into two materials types, silicon (Si) for RF power applications and gallium arsenide (GaAs) for microwave power applications. That is, Si-bipolar transistors and more recently, Si-MOSFETs have been used for high-power RF applications and GaAs metal-epitaxial-semiconductor field-effect transistors (MESFETs) have been used for power amplification at higher frequencies, such as above 3 GHz. Recently, in order to improve performance of high-power RF and microwave transistors, research has focused on materials other than silicon and GaAs, such as silicon carbide (SiC) and gallium nitride (GaN). However, it is difficult and expensive to develop processes that accommodates such materials.

In a GaAs MESFET, electrons are caused to move from the source to the drain by a positive drain source voltage. An input signal (voltage) on the gate is used to modulate the majority electron carriers, producing amplification. The length of the gate limits the maximum operational frequency of the transistor. While the GaAs MESFET is voltage driven, an Si-bipolar transistor is current driven, with the base current modulating the collector current. The length of the base is a main limiting factor of the upper frequency limit of a bipolar transistor.

The performance of a bipolar transistor or FET is often defined in terms of its transconductance. In general, the larger the transconductance of a device, the greater the gain the device can deliver. For a bipolar device, transconductance is defined as the ratio of the change in collector current to the change in base voltage over a defined interval on the collector-current-versus-base-voltage curve. For an FET, transconductance is the ratio of the change in drain current to the change in gate voltage over a defined interval on the drain-current-versus-gate-voltage curve.

As discussed above, the length and width of the gate is an important property of a FET. The shorter the gate, the better the high-frequency performance. The wider the gate, the higher the FET's transconductance and gate-to-source capacitance and the lower the source resistance. Increasing the gate width also increases the FET's maximum drain current, so power devices are typically wide-gate devices. The gates of power devices may be several millimeters wide. However, increasing the gate width also increases the gate resistance. When combined with the gate-to-source capacitance, the gate resistance forms a resistance-capacitance (RC) filter at the input of the FET, reducing the gain at high frequencies. The gate resistance also generates thermal noise, and degrades the noise figure of the transistor. Thus, it would be advantageous to be able to build a device with a large gate width that enhances the transconductance of the device, without the adverse effects of an increased gate resistance.

Semiconductor devices often include multiple layers of conductive, insulating, and semiconductive layers. Often, the desirable properties of such layers improve with the crystallinity of the layer. For example, the electron mobility and band gap of semiconductive layers improves as the crystallinity of the layer increases. Similarly, the free electron concentration of conductive layers and the electron charge displacement and electron energy recoverability of insulative or dielectric films improves as the crystallinity of these layers increases.

For many years, attempts have been made to grow various monolithic thin films on a foreign substrate such as silicon. To achieve optimal characteristics of the various monolithic layers, however, a monocrystalline film of high crystalline quality is needed. Attempts have been made, for example, to grow various monocrystalline layers on a substrate such as germanium, silicon, and various insulators. These attempts have generally been unsuccessful because lattice mismatches between the host crystal and the grown crystal have caused the resulting layer of monocrystalline material to be of low crystalline quality.

If a large area thin film of high quality monocrystalline material was available at low cost, a variety of semiconductor devices could advantageously be fabricated in or using that film at a low cost compared to the cost of fabricating such devices beginning with a bulk wafer of semiconductor material or in an epitaxial film of such material on a bulk wafer of semiconductor material. In addition, if a thin film of high quality monocrystalline material could be realized beginning with a bulk wafer such as a silicon wafer, an integrated device structure could be achieved that takes advantage of the best properties of both the silicon and the high quality monocrystalline material.

Accordingly, a need exists for a semiconductor structure that provides a high quality monocrystalline film or layer over another monocrystalline material and for a process for making such a structure so that true two-dimensional growth can be achieved for the formation of quality semiconductor structures, devices and integrated circuits having grown monocrystalline film with the same crystal orientation as an underlying substrate.

### BRIEF DESCRIPTION OF THE DRAWINGS

The following detailed description of preferred embodiments of the invention will be better understood when read in conjunction with the appended drawings. The present invention is illustrated by way of example and not limitation in the accompanying figures. Thus, it should be understood that the invention is not limited to the precise arrangements and instrumentalities shown. In the drawings, in which like references indicate similar elements:

FIGS. 1, 2, and 3 illustrate schematically, in cross section, device structures in accordance with various embodiments of the invention;

FIG. 4 illustrates graphically the relationship between maximum attainable film thickness and lattice mismatch between a host crystal and a grown crystalline overlayer;

FIG. 5 illustrates a high resolution Transmission Electron Micrograph of a structure including a monocrystalline accommodating buffer layer;

FIG. 6 illustrates an x-ray diffraction spectrum of a structure including a monocrystalline accommodating buffer layer;

FIG. 7 illustrates a high resolution Transmission Electron Micrograph of a structure including an amorphous oxide layer;

FIG. 8 illustrates an x-ray diffraction spectrum of a structure including an amorphous oxide layer;

FIGS. 9-12 illustrate schematically, in cross-section, the formation of a device structure in accordance with another embodiment of the invention;

FIGS. 13-16 illustrate a probable molecular bonding structure of the device structures illustrated in FIGS. 9-12;

FIGS. 17-20 illustrate schematically, in cross-section, the formation of a device structure in accordance with still another embodiment of the invention;

FIGS. 21-23 illustrate schematically, in cross-section, the formation of yet another embodiment of a device structure in accordance with the invention;

FIGS. 21-23 illustrate schematically, in cross section, the formation of a yet another embodiment of a device structure in accordance with the invention;

FIGS. 24 and 25 illustrate schematically, in cross section, device structures that can be used in accordance with various embodiments of the invention;

FIGS. 26-30 include illustrations of cross-sectional views of a portion of an integrated circuit that includes a compound semiconductor portion, a bipolar portion, and an MOS portion in accordance with the invention;

FIG. 31 illustrates schematically, in cross section, a stacked Si and GaAs device structure in accordance with an embodiment of the invention; and

FIG. 32 illustrates a top, plan view of the stacked Si and GaAs device structure of FIG. 31.

Skilled artisans will appreciate that elements in the figures are illustrated for simplicity and clarity and have not necessarily been drawn to scale. For example, the dimensions of some of the elements in the figures may be exaggerated relative to other elements to help to improve understanding of embodiments of the present invention.

### DETAILED DESCRIPTION OF THE INVENTION

As used herein, the terms “comprises,” “comprising,” or any other variation thereof, are intended to cover a non-exclusive inclusion, such that a process, method, article, or apparatus that comprises a list of elements is not required to include only those elements, but may include other elements not expressly listed or inherent to such process, method, article, or apparatus.

Referring now to the drawings, FIG. 1 is a schematic, cross-sectional view of a portion of a semiconductor structure 20 in accordance with an embodiment of the invention. The semiconductor structure 20 includes a monocrystalline substrate 22, an accommodating buffer layer 24 comprising a monocrystalline material, and a monocrystalline material layer 26. In this context, the term “monocrystalline” shall have the meaning commonly used within the semiconductor industry. The term refers to materials that are a single crystal or that are substantially a single crystal and includes those materials having a relatively small number of defects such as dislocations and the like as are commonly found in substrates of silicon or germanium or mixtures of silicon and germanium and epitaxial layers of such materials commonly found in the semiconductor industry.

In accordance with one embodiment of the invention, the structure 20 also includes an amorphous intermediate layer 28 positioned between the substrate 22 and the accommodating buffer layer 24. The structure 20 may also include a template layer 30 between the accommodating buffer layer 24 and the monocrystalline material layer 26. As will be explained more fully below, the template layer 30 helps to initiate the growth of the monocrystalline material layer 26 on the accommodating buffer layer 24. The amorphous intermediate layer 28 helps to relieve the strain in the accommodating buffer layer 24 and by doing so, aids in the growth of a high crystalline quality accommodating buffer layer.

The substrate 22, in accordance with an embodiment of the invention, is a monocrystalline semiconductor or compound semiconductor wafer, preferably of large diameter. The wafer can be of, for example, a material from Group IV of the periodic table, and preferably a material from Group IVB. Examples of Group IV semiconductor materials include silicon, germanium, mixed silicon and germanium, mixed silicon and carbon, mixed silicon, germanium and carbon, and the like. Preferably the substrate 22 is a wafer containing silicon or germanium, and most preferably is a high quality monocrystalline silicon wafer as used in the semiconductor industry.

The accommodating buffer layer 24 is preferably a monocrystalline oxide or nitride material epitaxially grown on the underlying substrate 22. In accordance with one embodiment of the invention, the amorphous intermediate layer 28 is grown on the substrate 22 at the interface between the substrate 22 and the growing accommodating buffer layer 24 by the oxidation of the substrate 22 during the growth of the accommodating buffer layer 24. The amorphous intermediate layer 28 serves to relieve strain that might otherwise occur in the monocrystalline accommodating buffer layer 24 as a result of differences in the lattice constants of the substrate 22 and the accommodating buffer layer 24. As used herein, lattice constant refers to the distance between atoms of a cell measured in the plane of the surface. If such strain is not relieved by the amorphous intermediate layer 28, the strain may cause defects in the crystalline structure of the accommodating buffer layer 24. Defects in the crystalline structure of the accommodating buffer layer 24, in turn, would make it difficult to achieve a high quality crystalline structure in the monocrystalline material layer 26 which may comprise a semiconductor material, a compound semiconductor material, or another type of material such as a metal or a non-metal.

The accommodating buffer layer 24 is preferably a monocrystalline oxide or nitride material selected for its crystalline compatibility with the underlying substrate 22 and with the overlying material layer 26. For example, the material of the accommodating buffer layer 24 could be an oxide or nitride having a lattice structure closely matched to the substrate 22 and to the subsequently applied monocrystalline material layer 26. Materials that are suitable for the accommodating buffer layer 24 include metal oxides such as the alkaline earth metal titanates, alkaline earth metal zirconates, alkaline earth metal hafnates, alkaline earth metal tantalates, alkaline earth metal ruthenates, alkaline earth metal niobates, alkaline earth metal vanadates, alkaline earth metal tin-based perovskites, lanthanum aluminate, lanthanum scandium oxide, and gadolinium oxide. Additionally, various nitrides such as gallium nitride, aluminum nitride, and boron nitride may also be used for the accommodating buffer layer 24. Most of these materials are insulators, although strontium ruthenate, for example, is a conductor. Generally, these materials are metal oxides or metal nitrides, and more particularly, these metal oxide or nitrides typically include at least two different metallic elements. In some specific applications, the metal oxides or nitrides may include three or more different metallic elements.

The material for the monocrystalline material layer 26 can be selected, as desired, for a particular structure or application. For example, the monocrystalline material of the monocrystalline material layer 26 may comprise a compound semiconductor that can be selected, as needed for a particular semiconductor structure, from any of the Group IIIA and VA elements (III-V semiconductor compounds), mixed III-V compounds, Group II(A or B) and VIA elements (II-VI semiconductor compounds), and mixed II-VI compounds. Examples include gallium arsenide (GaAs), gallium indium arsenide (GaInAs), gallium aluminum arsenide (GaAlAs), indium phosphide (InP), cadmium sulfide (CdS), cadmium mercury telluride (CdHgTe), zinc selenide (ZnSe), zinc sulfur selenide (ZnSSe), and the like. However, the monocrystalline material layer 26 may also comprise other semiconductor materials, metals, or non-metal materials that are used in the formation of semiconductor structures, devices and/or integrated circuits.

The amorphous intermediate layer 28 is preferably an oxide formed by the oxidation of the surface of the substrate 22, and more preferably is composed of a silicon oxide. The thickness of the intermediate layer 28 is sufficient to relieve strain attributed to mismatches between the lattice constants of the substrate 22 and the accommodating buffer layer 24. Typically, the intermediate layer 28 has a thickness in the range of approximately 0.5-5 nm.

Appropriate materials for template 30 are discussed below. Suitable template materials chemically bond to the surface of the accommodating buffer layer 24 at selected sites and provide sites for the nucleation of the epitaxial growth of the monocrystalline material layer 26. When used, the template layer 30 has a thickness ranging form about 1 to about 10 monolayers.

FIG. 2 illustrates, in cross section, a portion of a semiconductor structure 40 in accordance with a further embodiment of the invention. The structure 40 is similar to the previously described semiconductor structure 20, except that an additional buffer layer 32 is positioned between the accommodating buffer layer 24 and the monocrystalline material layer 26. Specifically, the additional buffer layer 32 is positioned between the template layer 30 and the overlying monocrystalline material layer 26. The additional buffer layer 32, formed of a semiconductor or compound semiconductor material when the monocrystalline material layer 26 comprises a semiconductor or compound semiconductor material, serves to provide a lattice compensation when the lattice constant of the accommodating buffer layer 24 cannot be adequately matched to the overlying monocrystalline semiconductor or compound semiconductor material layer 26.

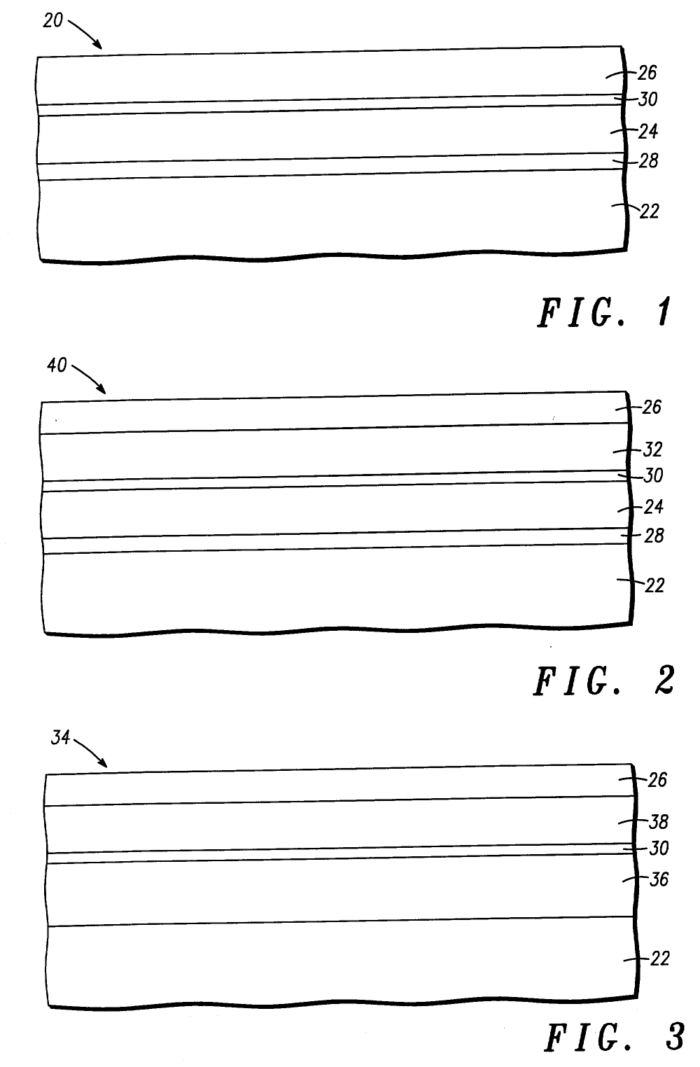

FIG. 3 schematically illustrates, in cross section, a portion of a semiconductor structure 34 in accordance with another exemplary embodiment of the invention. The structure 34 is similar to the structure 20, except that the structure 34 includes an amorphous layer 36, rather than the accommodating buffer layer 24 and the amorphous interface layer 28, and an additional monocrystalline layer 38.

As explained in greater detail below, the amorphous layer 36 may be formed by first forming an accommodating buffer layer and an amorphous interface layer in a similar manner to that described above. The additional monocrystalline layer 38 is then formed, by epitaxial growth, overlying the monocrystalline accommodating buffer layer. The accommodating buffer layer is then exposed to an anneal process to convert the monocrystalline accommodating buffer layer to an amorphous layer. The amorphous layer 36 formed in this manner comprises materials from both the accommodating buffer layer 24 and the amorphous intermediate layer 28, which amorphous layers may or may not amalgamate. Thus, amorphous layer 36 may comprise one or two amorphous layers. Formation of the amorphous layer 36 between the substrate 22 and the additional monocrystalline layer 26 (subsequent to additional layer 38 formation) relieves stresses between the substrate 22 and the additional monocyrstalline layer 38 and provides a true compliant substrate for subsequent processing, e.g., monocrystalline material layer 26 formation.

The processes described above in connection with FIGS. 1 and 2 are adequate for growing monocrystalline material layers over a monocrystalline substrate. However, the process described in connection with FIG. 3, which includes transforming a monocrystalline accommodating buffer layer to an amorphous oxide layer, may be better for growing monocrystalline material layers because it allows any strain in the monocrystalline material layer 26 to relax.

The additional monocrystalline layer 38 may include any of the materials described throughout this application in connection with either of the monocrystalline material layer 26 or the additional buffer layer 32. For example, when the monocrystalline material layer 26 comprises a semiconductor or compound semiconductor material, the additional layer 38 may include monocrystalline Group IV or monocrystalline compound semiconductor materials.

In accordance with one embodiment of the present invention, the additional monocrystalline layer 38 serves as an anneal cap during layer 36 formation and as a template for the subsequent formation of the monocrystalline material layer 26. Accordingly, additional monocrystalline layer 38 is preferably thick enough to provide a suitable template for growth of the monocrystalline material layer 26 (at least one monolayer) and thin enough to allow the additional monocrystalline layer 38 to form as a substantially defect free monocrystalline material.

In accordance with another embodiment of the invention, the additional monocrystalline layer 38 comprises monocrystalline material, such as a material discussed above in connection with the monocrystalline layer 26, that is thick enough to form devices within the additional layer 38. In this case, a semiconductor structure in accordance with the present invention does not include the monocrystalline material layer 26. That is, the semiconductor structure in accordance with this embodiment only includes one monocrystalline layer located above the amorphous layer 36.

The following non-limiting, illustrative examples illustrate various combinations of materials useful in structures 20, 40, and 34 in accordance with various alternative embodiments of the invention. These examples are merely illustrative, and it is not intended that the invention be limited to these illustrative examples.

### EXAMPLE 1

In accordance with one embodiment of the invention, the is a monocrystalline silicon substrate oriented in the (100) direction. The silicon substrate 22 can be, for example, a silicon substrate as is commonly used in making complementary metal oxide semiconductor (CMOS) integrated circuits having a diameter of about 200-300 mm. In accordance with this embodiment of the invention, the accommodating buffer layer 24 is a monocrystalline layer of Sr_{z}Ba_{1-z}TiO₃ where z ranges from 0 to 1 and the amorphous intermediate layer 28 is a layer of silicon oxide (SiOₓ) formed at the interface between the silicon substrate 22 and the accommodating buffer layer 24. The value of z is selected to obtain one or more lattice constants closely matched to corresponding lattice constants of the subsequently formed material layer 26. The accommodating buffer layer 24 can have a thickness of about 2 to about 100 nanometers (nm) and preferably has a thickness of about 5 nm. In general, it is desired to have an accommodating buffer layer 24 thick enough to isolate the monocrystalline material layer 26 from the substrate 22 to obtain the desired electrical and optical properties. Layers thicker than 100 nm usually provide little additional benefit while increasing cost unnecessarily; however, thicker layers may be fabricated if needed. The amorphous intermediate layer 28 of silicon oxide can have a thickness of about 0.5-5 nm, and preferably a thickness of about 1 to 2 nm.

In accordance with this embodiment of the invention, the monocrystalline material layer 26 is a compound semiconductor layer of gallium arsenide (GaAs) or aluminum gallium arsenide (AlGaAs) having a thickness of about 1 nm to about 100 micrometers (μm) and preferably a thickness of about 0.5 μm to 10 μm. The thickness generally depends on the application for which the layer is being prepared. To facilitate the epitaxial growth of the gallium arsenide or aluminum gallium arsenide on the monocrystalline oxide, a template layer is formed by capping the oxide layer. The template layer is preferably 1-10 monolayers of Ti—As, Sr—O—As, Sr—Ga—O, or Sr—Al—O. By way of a preferred example, 1-2 monolayers of Ti—As or Sr—Ga—O have been illustrated to successfully grow GaAs layers.

### EXAMPLE 2

In accordance with a further embodiment of the invention, the substrate 22 is a monocrystalline silicon substrate as described above. The accommodating buffer layer 24 is a monocrystalline oxide of strontium or barium zirconate or hafnate in a cubic or orthorhombic phase with an amorphous intermediate layer 28 of silicon oxide formed at the interface between the silicon substrate 22 and the accommodating buffer layer 24. The accommodating buffer layer 24 can have a thickness of about 2-100 nm and preferably has a thickness of at least 5 nm to ensure adequate crystalline and surface quality and is formed of a monocrystalline SrZrO₃, BaZrO₃, SrHfO₃, BaSnO₃ or BaHfO₃. For example, a monocrystalline oxide layer of BaZrO₃ can grow at a temperature of about 700 degrees C. The lattice structure of the resulting crystalline oxide exhibits a 45 degree rotation with respect to the substrate silicon lattice structure.

An accommodating buffer layer formed of these zirconate or hafnate materials is suitable for the growth of a monocrystalline material layer which comprises compound semiconductor materials in the indium phosphide (InP) system. In this system, the compound semiconductor material can be, for example, indium phosphide (InP), indium gallium arsenide (InGaAs), aluminum indium arsenide, (AlInAs), or aluminum gallium indium arsenic phosphide (AlGaInAsP), having a thickness of about 1.0 nm to 10 μm. A suitable template, i.e., the template layer 30, for this structure is 1-10 monolayers of zirconium—arsenic (Zr—As), zirconium—phosphorus (Zr—P), hafnium—arsenic (Hf—As), hafnium—phosphorus (Hf-P), strontium—oxygen—arsenic (Sr—O—As), strontium—oxygen—phosphorus (Sr—O—P), barium—oxygen—arsenic (Ba—O—As), indium—strontium—oxygen (In—Sr—O), or barium—oxygen—phosphorus (Ba—O—P), and preferably 1-2 monolayers of one of these materials. By way of an example, for a barium zirconate accommodating buffer layer, the surface is terminated with 1-2 monolayers of zirconium followed by deposition of 1-2 monolayers of arsenic to form a Zr—As template. A monocrystalline layer of the compound semiconductor material from the indium phosphide system is then grown on the template layer. The resulting lattice structure of the compound semiconductor material exhibits a 45 degree rotation with respect to the accommodating buffer layer lattice structure and a lattice mismatch to (100) InP of less than 2.5%, and preferably less than about 1.0%.

### EXAMPLE 3

In accordance with a further embodiment of the invention, a structure is provided that is suitable for the growth of an epitaxial film of a monocrystalline material comprising a II-VI material overlying a silicon substrate. The substrate is preferably a silicon wafer as described above. A suitable accommodating buffer layer material is SrₓBa₁₋ₓTiO₃, where x ranges from 0 to 1, having a thickness of about 2-100 nm and preferably a thickness of about 5-15 nm. Where the monocrystalline layer comprises a compound semiconductor material, the II-VI compound semiconductor material can be, for example, zinc selenide (ZnSe) or zinc sulfur selenide (ZnSSe). A suitable template for this material system includes 1-10 monolayers of zinc-oxygen (Zn—O) followed by 1-2 monolayers of an excess of zinc followed by the selenidation of zinc on the surface. Alternatively, a template can be, for example, 1-10 monolayers of strontium-sulfur (Sr—S) followed by the ZnSeS.

### EXAMPLE 4

This embodiment of the invention is an example of the structure 40 illustrated in FIG. 2. The substrate 22, accommodating buffer layer 24, and monocrystalline material layer 26 can be similar to those described in example 1. In addition, an additional buffer layer 32 serves to alleviate any strains that might result from a mismatch of the crystal lattice of the accommodating buffer layer 24 and the lattice of the monocrystalline material. The additional buffer layer 32 can be a layer of germanium or a GaAs, an aluminum gallium arsenide (AlGaAs), an indium gallium phosphide (InGaP), an aluminum gallium phosphide (AlGaP), an indium gallium arsenide (InGaAs), an aluminum indium phosphide (AlInP), a gallium arsenide phosphide (GaAsP), or an indium gallium phosphide (InGaP) strain compensated superlattice. In accordance with one aspect of this embodiment, the additional buffer layer 32 includes a GaAsₓP₁₋ₓ superlattice, where the value of x ranges from 0 to 1. In accordance with another aspect, the additional buffer layer 32 includes an In_{y}Ga_{1-y}P superlattice, where the value of y ranges from 0 to 1. By varying the value of x or y, as the case may be, the lattice constant is varied from bottom to top across the superlattice to create a match between lattice constants of the underlying oxide and the overlying monocrystalline material which in this example is a compound semiconductor material. The compositions of other compound semiconductor materials, such as those listed above, may be similarly varied to manipulate the lattice constant of the additional buffer layer 32 in a like manner. The superlattice can have a thickness of about 50-500 nm and preferably has a thickness of about 100-200 nm. The template for this structure can be the same as that described in example 1. Alternatively, the additional buffer layer 32 can be a layer of monocrystalline germanium having a thickness of 1-50 nm and preferably having a thickness of about 2-20 nm. In using a germanium buffer layer, a template layer of either germanium—strontium (Ge—Sr) or germanium—titanium (Ge—Ti) having a thickness of about one monolayer can be used as a nucleating site for the subsequent growth of the monocrystalline material layer 26 that in this example is a compound semiconductor material. The formation of the oxide layer is capped with either a monolayer of strontium or a monolayer of titanium to act as a nucleating site for the subsequent deposition of the monocrystalline germanium. The monolayer of strontium or titanium provides a nucleating site to which the first monolayer of germanium can bond.

### EXAMPLE 5

This example also illustrates materials useful in the structure 40 illustrated in FIG. 2. The substrate 22, accommodating buffer layer 24, monocrystalline material layer 26 and template layer 30 can be the same as those described above in example 2. The additional buffer layer 32 is inserted between the accommodating buffer layer 24 and the overlying monocrystalline material layer 26. The additional buffer layer 32, a further monocrystalline material that in this instance comprises a semiconductor material, can be, for example, a graded layer of indium gallium arsenide (InGaAs) or indium aluminum arsenide (InAlAs). In accordance with one aspect of this embodiment, the additional buffer layer 32 includes InGaAs, in which the indium composition varies from 0 to about 50%. The additional buffer layer 32 preferably has a thickness of about 10-30 nm. Varying the composition of the additional buffer layer 32 from GaAs to InGaAs serves to provide a lattice match between the underlying monocrystalline oxide material and the overlying layer of monocrystalline material that in this example is a compound semiconductor material. Such a buffer layer is especially advantageous if there is a lattice mismatch between the accommodating buffer layer 24 and the monocrystalline material layer 26.

### EXAMPLE 6

This example provides exemplary materials useful in the structure 34 illustrated in FIG. 3. The substrate 22, template layer 30, and monocrystalline material layer 26 may be the same as those described above in connection with example 1.

The amorphous layer 36 is an amorphous oxide layer that is suitably formed of a combination of amorphous intermediate layer materials (e.g., amorphous intermediate layer 28 materials as described above) and accommodating buffer layer materials (e.g., accommodating buffer layer 24 materials as described above). For example, the amorphous layer 36 may include a combination of SiO_{X} and Sr_{z}Ba_{1-z} TiO₃ (where z ranges from 0 to 1), which combine or mix, at least partially, during an anneal process to form the amorphous oxide layer 36.

The thickness of the amorphous layer 36 may vary from application to application and may depend on such factors as desired insulating properties of the amorphous layer 36, type of monocrystalline material of the amorphous layer 26, and the like. In accordance with one exemplary aspect of the present embodiment, the amorphous layer 36 has a thickness of about 2 nm to about 100 nm, preferably about 2-10 nm, and more preferably about 5-6 nm.

The additional monocrystalline layer 38 comprises a monocrystalline material that can be grown epitaxially over a monocrystalline oxide material such as the material used to form the accommodating buffer layer 24. In accordance with one embodiment of the invention, the additional monocrystalline layer 38 includes the same materials as those comprising the amorphous layer 26. For example, if the amorphous layer 26 includes GaAs, the additional monocrystalline layer 38 also includes GaAs. However, in accordance with other embodiments of the present invention, the additional monocrystalline layer 38 may include materials different from those used to form the amorphous layer 26. In accordance with one exemplary embodiment of the invention, the additional monocrystalline layer 38 is about 1 monolayer to about 100 nm thick.

Referring again to FIGS. 1-3, the substrate 22 is a monocrystalline substrate such as a monocrystalline silicon or gallium arsenide substrate. The crystalline structure of the substrate 22 is characterized by a lattice constant and by a lattice orientation. In similar manner, the accommodating buffer layer 24 is also a monocrystalline material, the lattice of which is characterized by a lattice constant and a crystal orientation. The lattice constants of the accommodating buffer layer 24 and the substrate 22 must be closely matched or, alternatively, must be such that upon rotation of one crystal orientation with respect to the other crystal orientation, a substantial match in lattice constants is achieved. In this context the terms “substantially equal” and “substantially matched” mean that there is sufficient similarity between the lattice constants to permit the growth of a high quality crystalline layer on the underlying layer.

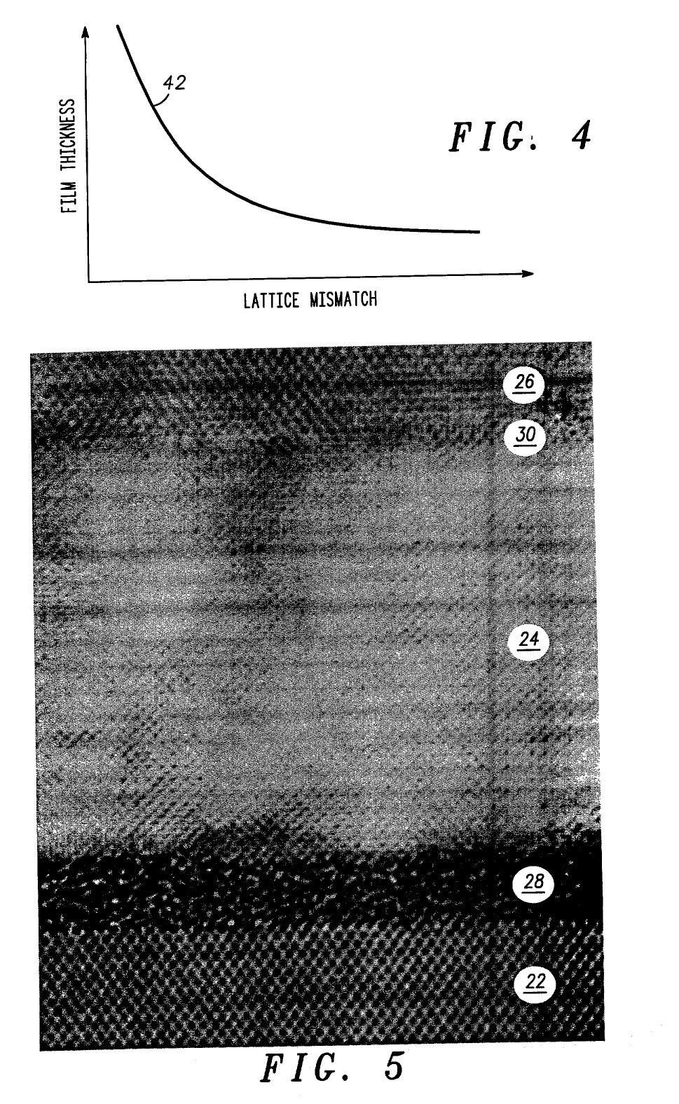

FIG. 4 illustrates graphically the relationship of the achievable thickness of a grown crystal layer of high crystalline quality as a function of the mismatch between the lattice constants of the host crystal and the grown crystal. Curve 42 illustrates the boundary of high crystalline quality material. The area to the right of curve 42 represents layers that have a large number of defects. With no lattice mismatch, it is theoretically possible to grow an infinitely thick, high quality epitaxial layer on the host crystal. As the mismatch in lattice constants increases, the thickness of achievable, high quality crystalline layer decreases rapidly. As a reference point, for example, if the lattice constants between the host crystal and the grown layer are mismatched by more than about 2%, monocrystalline epitaxial layers in excess of about 20 nm cannot be achieved.

In accordance with one embodiment of the invention, the substrate 22 is a (100) or (111) oriented monocrystalline silicon wafer and the accommodating buffer layer 24 is a layer of strontium barium titanate. Substantial matching of lattice constants between these two materials is achieved by rotating the crystal orientation of the titanate material by 45° with respect to the crystal orientation of the silicon wafer. The inclusion in the structure of the amorphous intermediate layer 28, a silicon oxide layer in this example, if it is of sufficient thickness, serves to reduce strain in the titanate monocrystalline layer that might result from any mismatch in the lattice constants of the host silicon wafer and the grown titanate layer. As a result, in accordance with an embodiment of the invention, a high quality, thick, monocrystalline titanate layer is achievable.

Still referring to FIGS. 1-3, the material layer 26 is a layer of epitaxially grown monocrystalline material that is characterized by a crystal lattice constant and a crystal orientation. In accordance with one embodiment of the invention, the lattice constant of the material layer 26 differs from the lattice constant of the substrate 22. To achieve high crystalline quality in this epitaxially grown monocrystalline layer, the accommodating buffer layer 24 must be of high crystalline quality. In addition, in order to achieve high crystalline quality in the material layer 26, substantial matching between the crystal lattice constant of the host crystal, in this case, the monocrystalline accommodating buffer layer 24, and the grown crystal is desired. With properly selected materials this substantial matching of lattice constants is achieved as a result of rotation of the crystal orientation of the grown crystal with respect to the orientation of the host crystal. For example, if the grown crystal is gallium arsenide, aluminum gallium arsenide, zinc selenide, or zinc sulfur selenide and the accommodating buffer layer 24 is monocrystalline SrₓBa₁₋ₓTiO₃, substantial matching of crystal lattice constants of the two materials is achieved, where the crystal orientation of the grown layer is rotated by 45° with respect to the orientation of the host monocrystalline oxide. Similarly, if the host material is a strontium or barium zirconate or a strontium or barium hafnate or barium tin oxide and the material layer 26 is indium phosphide or gallium indium arsenide or aluminum indium arsenide, substantial matching of crystal lattice constants can be achieved by rotating the orientation of the grown crystal layer by 45° with respect to the host oxide crystal. In some instances, a crystalline semiconductor buffer layer between the host oxide and the grown monocrystalline material layer 26 can be used to reduce strain in the grown monocrystalline material layer 26 that might result from small differences in lattice constants. Better crystalline quality in the grown monocrystalline material layer 26 can thereby be achieved.

The following example illustrates a process, in accordance with one embodiment of the invention, for fabricating a semiconductor structure such as the structures depicted in FIGS. 1-3. The process starts by providing a monocrystalline semiconductor substrate comprising silicon or germanium. In accordance with a preferred embodiment of the invention, the semiconductor substrate is a silicon wafer having a (100) orientation. The substrate is preferably oriented on axis or, at most, about 4° off axis. At least a portion of the semiconductor substrate has a bare surface, although other portions of the substrate, as described below, may encompass other structures. The term “bare” in this context means that the surface in the portion of the substrate has been cleaned to remove any oxides, contaminants, or other foreign material. As is well known, bare silicon is highly reactive and readily forms a native oxide. The term “bare” is intended to encompass such a native oxide. A thin silicon oxide may also be intentionally grown on the semiconductor substrate, although such a grown oxide is not essential to the process in accordance with the invention. In order to epitaxially grow a monocrystalline oxide layer overlying the monocrystalline substrate, the native oxide layer must first be removed to expose the crystalline structure of the underlying substrate. The following process is preferably carried out by molecular beam epitaxy (MBE), although other epitaxial processes may also be used in accordance with the present invention. The native oxide can be removed by first thermally depositing a thin layer of strontium, barium, a combination of strontium and barium, or other alkali earth metals or combinations of alkali earth metals in an MBE apparatus. In the case where strontium is used, the substrate is then heated to a temperature of about 850° C. to cause the strontium to react with the native silicon oxide layer. The strontium serves to reduce the silicon oxide to leave a silicon oxide-free surface. The resultant surface, which exhibits an ordered 2×1 structure, includes strontium, oxygen, and silicon. The ordered 2×1 structure forms a template for the ordered growth of an overlying layer of a monocrystalline oxide. The template provides the necessary chemical and physical properties to nucleate the crystalline growth of an overlying layer.

In accordance with an alternate embodiment of the invention, the native silicon oxide can be converted and the substrate surface can be prepared for the growth of a monocrystalline oxide layer by depositing an alkali earth metal oxide, such as strontium oxide, strontium barium oxide, or barium oxide, onto the substrate surface by MBE at a low temperature and by subsequently heating the structure to a temperature of about 850° C. At this temperature a solid state reaction takes place between the strontium oxide and the native silicon oxide causing the reduction of the native silicon oxide and leaving an ordered 2×1 structure with strontium, oxygen, and silicon remaining on the substrate surface. Again, this forms a template for the subsequent growth of an ordered monocrystalline oxide layer.

Following the removal of the silicon oxide from the surface of the substrate, in accordance with one embodiment of the invention, the substrate is cooled to a temperature in the range of about 200-800° C. and a layer of strontium titanate is grown on the template layer by molecular beam epitaxy. The MBE process is initiated by opening shutters in the MBE apparatus to expose strontium, titanium and oxygen sources. The ratio of strontium and titanium is approximately 1:1. The partial pressure of oxygen is initially set at a minimum value to grow stochiometric strontium titanate at a growth rate of about 0.3-0.5 nm per minute. After initiating growth of the strontium titanate, the partial pressure of oxygen is increased above the initial minimum value. The overpressure of oxygen causes the growth of an amorphous silicon oxide layer at the interface between the underlying substrate and the growing strontium titanate layer. The growth of the silicon oxide layer results from the diffusion of oxygen through the growing strontium titanate layer to the interface where the oxygen reacts with silicon at the surface of the underlying substrate. The strontium titanate grows as an ordered (100) monocrystal with the (100) crystalline orientation rotated by 45° with respect to the underlying substrate. Strain that otherwise might exist in the strontium titanate layer because of the small mismatch in lattice constant between the silicon substrate and the growing crystal is relieved in the amorphous silicon oxide intermediate layer.

After the strontium titanate layer has been grown to the desired thickness, the monocrystalline strontium titanate is capped by a template layer that is conducive to the subsequent growth of an epitaxial layer of a desired monocrystalline material. For example, for the subsequent growth of a monocrystalline compound semiconductor material layer of gallium arsenide, the MBE growth of the strontium titanate monocrystalline layer can be capped by terminating the growth with 1-2 monolayers of titanium, 1-2 monolayers of titanium-oxygen or with 1-2 monolayers of strontium-oxygen. Following the formation of this capping layer, arsenic is deposited to form a Ti—As bond, a Ti—O—As bond or a Sr—O—As. Any of these form an appropriate template for deposition and formation of a gallium arsenide monocrystalline layer. Following the formation of the template, gallium is subsequently introduced to the reaction with the arsenic and gallium arsenide forms. Alternatively, gallium can be deposited on the capping layer to form a Sr—O—Ga bond, and arsenic is subsequently introduced with the gallium to form the GaAs.

FIG. 5 is a high resolution Transmission Electron Micrograph (TEM) of semiconductor material manufactured in accordance with one embodiment of the present invention. Single crystal SrTiO₃ accommodating buffer layer 24 was grown epitaxially on silicon substrate 22. During this growth process, the amorphous intermediate layer 28 is formed, which relieves strain due to lattice mismatch. The monocrystalline material layer 26 formed of a GaAs compound semiconductor material was then grown epitaxially using the template layer 30.

FIG. 6 illustrates an x-ray diffraction spectrum taken on a structure including the monocrystalline material layer 26 comprising GaAs grown on the silicon substrate 22 using the accommodating buffer layer 24. The peaks in the spectrum indicate that both the accommodating buffer layer 24 and the GaAs monocrystalline material layer 26 are single crystal and (100) orientated.

The structure 40 illustrated in FIG. 2 can be formed by the process discussed above with the addition of an additional buffer layer deposition step. The additional buffer layer 32 is formed overlying the template layer 30 before the deposition of the monocrystalline material layer 26. If the additional buffer layer 32 is a monocrystalline material comprising a compound semiconductor superlattice, such a superlattice can be deposited, by MBE for example, on the template layer 30 described above. If instead the additional buffer layer 32 is a monocrystalline material layer comprising a layer of germanium, the process above is modified to cap the strontium titanate monocrystalline layer with a final layer of either strontium or titanium and then by depositing germanium to react with the strontium or titanium. The germanium additional buffer layer 32 can then be deposited directly on this template.

The structure 34 illustrated in FIG. 3 may be formed by growing the accommodating buffer layer 24, forming an amorphous oxide layer over the substrate 22, and growing the additional monocrystalline layer 38 over the accommodating buffer layer 24, as described above. The accommodating buffer layer 24 and the amorphous oxide layer 28 are then exposed to an anneal process sufficient to change the crystalline structure of the accommodating buffer layer 24 from monocrystalline to amorphous, thereby forming an amorphous layer such that the combination of the amorphous oxide layer 28 and the now amorphous accommodating buffer layer 24 form a single amorphous oxide layer 36. The monocrystalline material layer 26 is then grown over the additional monocrystalline layer 38. Alternatively, the anneal process may be carried out subsequent to growth of the monocrystalline material layer 26.

In accordance with one aspect of this embodiment, the amorphous layer 36 is formed by exposing the substrate 22, the accommodating buffer layer 24, the amorphous oxide layer 28, and the additional monocrystalline layer 38 to a rapid thermal anneal process with a peak temperature of about 700° C. to about 1000° C. and a process time of about 5 seconds to about 10 minutes. However, other suitable anneal processes may be employed to convert the accommodating buffer layer 24 to an amorphous layer in accordance with the present invention. For example, laser annealing, electron beam annealing, or “conventional” thermal annealing processes (in the proper environment) may be used to form the amorphous layer 36. When conventional thermal annealing is used to form the amorphous layer 36, an overpressure of one or more constituents of the template layer 30 may be required to prevent degradation of the additional monocrystalline layer 38 during the anneal process. For example, when the additional layer 38 includes GaAs, the anneal environment preferably includes an overpressure of arsenic to mitigate degradation of the additional layer 38.

As noted above, the additional layer 38 of the structure 34 may include any materials suitable for either of the additional buffer layer 32 or the monocrystalline material layer 26. Accordingly, any deposition or growth methods described in connection with either the additional buffer layer 32 or the monocrystalline material layer 26, may be used to deposit the additional layer 38.

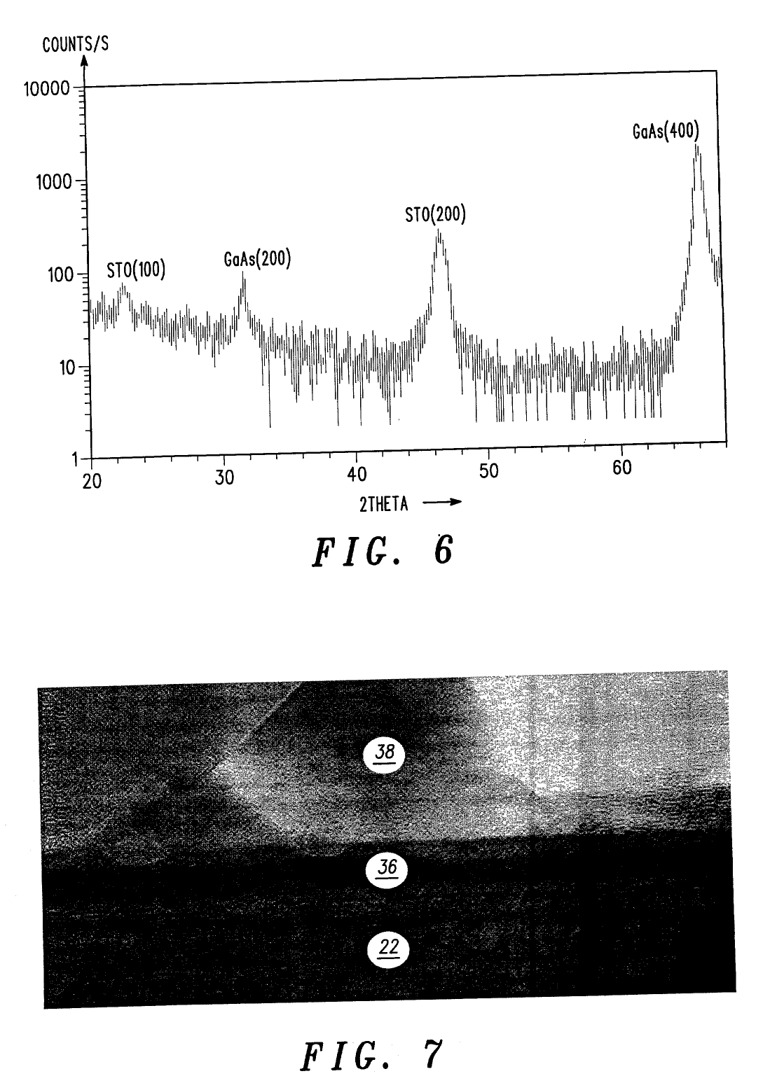

FIG. 7 is a high resolution TEM of semiconductor material manufactured in accordance with the embodiment of the invention illustrated in FIG. 3. In accordance with this embodiment, a single crystal SrTiO₃ accommodating buffer layer 24 was grown epitaxially on the silicon substrate 22. During this growth process, an amorphous intermediate layer forms as described above. Next, the additional monocrystalline layer 38 comprising a compound semiconductor layer of GaAs is formed above the accommodating buffer layer 24 and the accommodating buffer layer 24 is exposed to an anneal process to form the amorphous oxide layer 36.

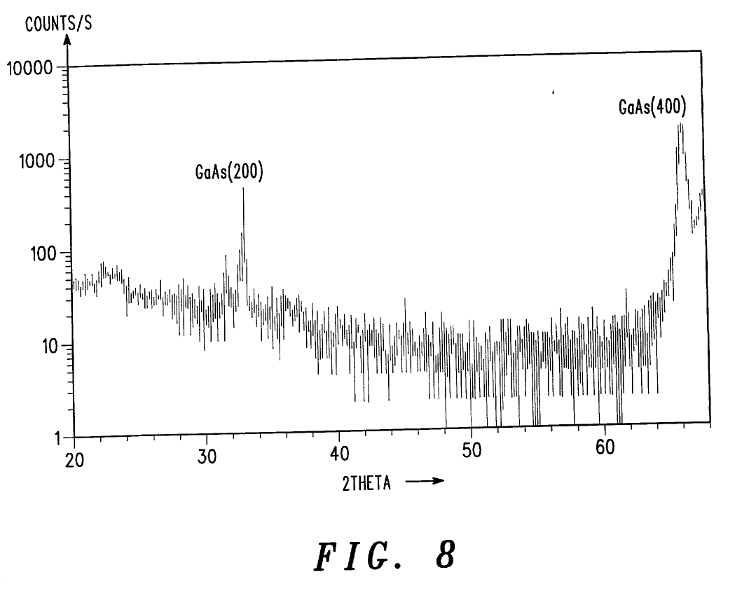

FIG. 8 illustrates an x-ray diffraction spectrum taken on a structure including the additional monocrystalline layer 38 comprising a GaAs compound semiconductor layer and the amorphous oxide layer 36 formed on the silicon substrate 22. The peaks in the spectrum indicate that the GaAs compound semiconductor layer 38 is single crystal and (100) orientated and the lack of peaks around 40 to 50 degrees indicates that the amorphous layer 36 is indeed amorphous.

The process described above illustrates a process for forming a semiconductor structure including a silicon substrate, an overlying oxide layer, and a monocrystalline material layer comprising a gallium arsenide compound semiconductor layer by the process of MBE. The process can also be carried out by the process of chemical vapor deposition (CVD), metal organic chemical vapor deposition (MOCVD), migration enhanced epitaxy (MEE), atomic layer epitaxy (ALE), physical vapor deposition (PVD), chemical solution deposition (CSD), pulsed laser deposition (PLD), or the like. Further, by a similar process, other monocrystalline accommodating buffer layers such as alkaline earth metal titanates, zirconates, hafnates, tantalates, vanadates, ruthenates, and niobates, peroskite oxides such as alkaline earth metal tin-based perovskites, lanthanum aluminate, lanthanum scandium oxide, and gadolinium oxide can also be grown. Further, by a similar process such as MBE, other monocrystalline material layers comprising other III-V and II-VI monocrystalline compound semiconductors, semiconductors, metals and non-metals can be deposited overlying the monocrystalline oxide accommodating buffer layer.

Each of the variations of the monocrystalline material layer 26 and the monocrystalline oxide accommodating buffer layer 24 uses an appropriate template layer 30 for initiating the growth of the monocrystalline material layer 26. For example, if the accommodating buffer layer 24 is an alkaline earth metal zirconate, the oxide can be capped by a thin layer of zirconium. The deposition of zirconium can be followed by the deposition of arsenic or phosphorus to react with the zirconium as a precursor to depositing indium gallium arsenide, indium aluminum arsenide, or indium phosphide respectively. Similarly, if the monocrystalline oxide accommodating buffer layer 24 is an alkaline earth metal hafnate, the oxide layer can be capped by a thin layer of hafnium. The deposition of hafnium is followed by the deposition of arsenic or phosphorous to react with the hafnium as a precursor to the growth of an indium gallium arsenide, indium aluminum arsenide, or indium phosphide layer, respectively. In a similar manner, strontium titanate can be capped with a layer of strontium or strontium and oxygen and barium titanate can be capped with a layer of barium or barium and oxygen. Each of these depositions can be followed by the deposition of arsenic or phosphorus to react with the capping material to form the template layer 30 for the deposition of the monocrystalline material layer 26 comprising compound semiconductors such as indium gallium arsenide, indium aluminum arsenide, or indium phosphide.

The formation of a device structure in accordance with another embodiment of the invention is illustrated schematically in cross-section in FIGS. 9-12. Like the previously described embodiments referred to in FIGS. 1-3, this embodiment of the invention involves the process of forming a compliant substrate utilizing the epitaxial growth of single crystal oxides, such as the formation of the accommodating buffer layer 24 previously described with reference to FIGS. 1 and 2 and the amorphous layer 36 previously described with reference to FIG. 3, and the formation of the template layer 30. However, the embodiment illustrated in FIGS. 9-12 utilizes a template that includes a surfactant to facilitate layer-by-layer monocrystalline material growth.

Referring now to FIG. 9, an amorphous intermediate layer 58 is grown on a substrate 52 at the interface between the substrate 52 and a growing accommodating buffer layer 54, which is preferably a monocrystalline crystal oxide layer, by the oxidation of the substrate 52 during the growth of the accommodating buffer layer 54. The accommodating buffer layer 54 is preferably a monocrystalline oxide material such as a monocrystalline layer of Sr_{z}Ba_{1-z}TiO₃ where z ranges from 0 to 1. However, the accommodating buffer layer 54 may also comprise any of those compounds previously described with reference to the accommodating buffer layer 24 in FIGS. 1-2 and any of those compounds previously described with reference to the amorphous layer 36 in FIG. 3 that is formed from the accommodating buffer layer 24 and the amorphous intermediate layer 28 referenced in FIGS. 1 and 2.

The accommodating buffer layer 54 is grown with a strontium (Sr) terminated surface represented in FIG. 9 by hatched line 55 which is followed by the addition of a template layer 60 that includes a surfactant layer 61 and a capping layer 63 as illustrated in FIGS. 10 and 11. the surfactant layer 61 may comprise, but is not limited to, elements such as Al, In and Ga, but will be dependent upon the composition of the accommodating buffer layer 54 and an overlying layer 66 of monocrystalline material for optimal results. In one exemplary embodiment, aluminum (Al) is used for the surfactant layer 61, which functions to modify the surface and surface energy of the accommodating buffer layer 54. Preferably, the surfactant layer 61 is epitaxially grown, to a thickness of one to two monolayers, over the accommodating buffer layer 54, as illustrated in FIG. 10, by way of MBE, although other epitaxial processes may also be performed including CVD, MOCVD, MEE, ALE, PVD, CSD, PLD, or the like.

The surfactant layer 61 is then exposed to a Group V element such as arsenic, for example, to form the capping layer 63 illustrated in FIG. 11. The surfactant layer 61 may be exposed to a number of materials to create the capping layer 63 such as elements that include, but are not limited to, As, P, Sb and N. The surfactant layer 61 and the capping layer 63 combine to form the template layer 60.

A monocrystalline material layer 66, which in this example is a compound semiconductor material such as GaAs, is then deposited via MBE, CVD, MOCVD, MEE, ALE, PVD, CSD, PLD, and the like to form the final structure illustrated in FIG. 12.

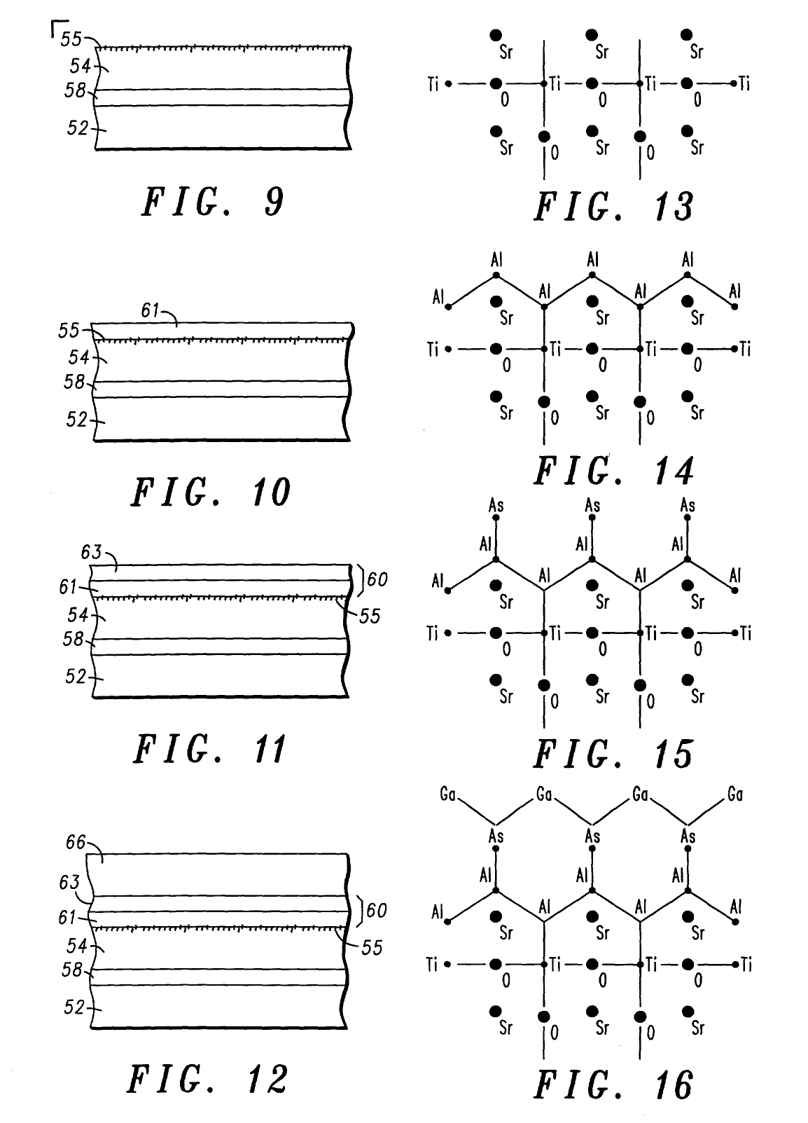

FIGS. 13-16 illustrate possible molecular bond structures for a specific example of a compound semiconductor structure formed in accordance with the embodiment of the invention illustrated in FIGS. 9-12. More specifically, FIGS. 13-16 illustrate the growth of GaAs (layer 66) on the strontium terminated surface of a strontium titanate monocrystalline oxide (layer 54) using a surfactant containing template (layer 60).

The growth of a monocrystalline material layer 66, such as GaAs, on the accommodating buffer layer 54 such as a strontium titanium oxide over the amorphous intermediate layer 58 and the substrate 52, both of which may comprise materials previously described with reference to the amorphous intermediate layer 28 and the substrate 22, respectively in FIGS. 1 and 2, illustrates a critical thickness of about 1000 Angstroms where the two-dimensional (2D) and three-dimensional (3D) growth shifts because of the surface energies involved. In order to maintain a true layer-by-layer growth (Frank Van der Mere growth), the following relationship must be satisfied:

δ_{STO}>(δ_{INT}+δ_{GaAs})

where the surface energy of the monocrystalline oxide accommodating buffer layer 54 must be greater than the surface energy of the amorphous interface layer 58 added to the surface energy of the GaAs monocrystalline material layer 66. Since it is impracticable to satisfy this equation, a surfactant containing template was used, as described above with reference to FIGS. 10-12, to increase the surface energy of the monocrystalline oxide accommodating buffer layer 54 and also to shift the crystalline structure of the template to a diamond-like structure that is in compliance with the original GaAs layer.

FIG. 13 illustrates the molecular bond structure of a strontium terminated surface of a strontium titanate monocrystalline oxide layer (layer 54). An aluminum surfactant layer (layer 61) is deposited on top of the strontium terminated surface 55 and bonds with the surface 55 as illustrated in FIG. 14, which reacts to form the capping layer 63 comprising a monolayer of Al₂Sr having the molecular bond structure illustrated in FIG. 14 which forms a diamond-like structure with an sp³ hybrid terminated surface that is compliant with compound semiconductors such as GaAs. The structure is then exposed to As to form a layer of AlAs as shown in FIG. 15. GaAs is then deposited to complete the molecular bond structure illustrated in FIG. 16 that has been obtained by 2D growth. The GaAs can be grown to any thickness for forming other semiconductor structures, devices, or integrated circuits. Alkaline earth metals such as those in Group IIA are those elements preferably used to form the capping surface of the monocrystalline oxide layer 54 because they are capable of forming a desired molecular structure with aluminum.

In this embodiment, a surfactant containing template layer (layer 60) aids in the formation of a compliant substrate for the monolithic integration of various material layers including those comprised of Group III-V compounds to form high quality semiconductor structures, devices and integrated circuits. For example, a surfactant containing template may be used for the monolithic integration of a monocrystalline material layer such as a layer comprising Germanium (Ge), for example, to form high efficiency photocells.

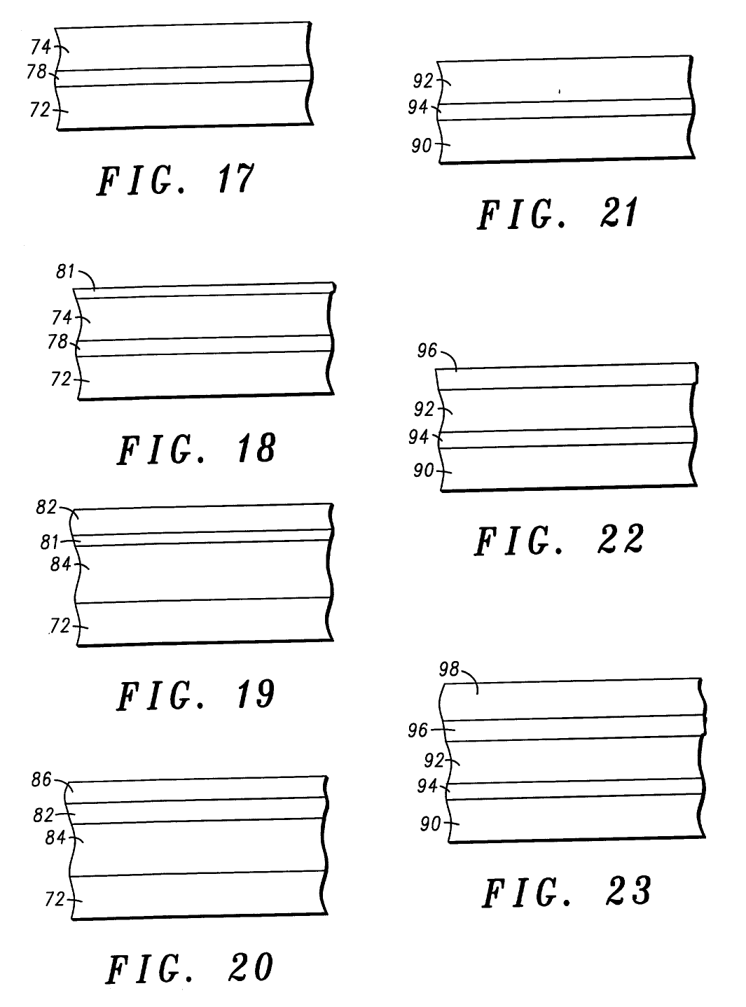

Turning now to FIGS. 17-20, the formation of a device structure in accordance with still another embodiment of the invention is illustrated in cross-section. This embodiment utilizes the formation of a compliant substrate that relies on the epitaxial growth of single crystal oxides on silicon followed by the epitaxial growth of single crystal silicon onto the oxide.

An accommodating buffer layer 74 such as a monocrystalline oxide layer is first grown on a substrate 72, such as silicon, with an amorphous interface layer 78 as illustrated in FIG. 17. The monocrystalline oxide accommodating buffer layer 74 may comprise any of those materials previously discussed with reference to the accommodating buffer layer 24 in FIGS. 1 and 2, while the amorphous interface layer 78 preferably comprises any of those materials previously described with reference to the amorphous intermediate layer 28 illustrated in FIGS. 1 and 2. The substrate 72, although preferably silicon, may also comprise any of those materials previously described with reference to the substrate 22 in FIGS. 1-3.

Next, a silicon layer 81 is deposited over the monocrystalline oxide accommodating buffer layer 74 via MBE, CVD, MOCVD, MEE, ALE, PVD, CSD, PLD, and the like as illustrated in FIG. 18 with a thickness of a few hundred Angstroms, but preferably with a thickness of about 50 Angstroms. The monocrystalline oxide accommodating buffer layer 74 preferably has a thickness of about 20 to 100 Angstroms.

Rapid thermal annealing is then conducted in the presence of a carbon source such as acetylene or methane, for example at a temperature within a range of about 800° C. to 1000° C. to form a capping layer 82 and a silicate amorphous layer 84. However, other suitable carbon sources may be used as long as the rapid thermal annealing step amorphizes the monocrystalline oxide accommodating buffer layer 74 into the silicate amorphous layer 84 and carbonizes the silicon layer 81 to form the capping layer 82, which in this example is a silicon carbide (SiC) layer as illustrated in FIG. 19. The formation of the amorphous layer 84 is similar to the formation of the amorphous layer 36 illustrated in FIG. 3 and may comprise any of those materials described with reference to the amorphous layer 36 in FIG. 3, but the preferable material will be dependent upon the capping layer 82.

Finally, a compound semiconductor layer 86, such as gallium nitride (GaN) is grown over the SiC surface of the capping layer 82 by way of MBE, CVD, MOCVD, MEE, ALE, PVD, CSD, PLD, or the like to form a high quality compound semiconductor material for device formation.

More specifically, the deposition of GaN and GaN based systems such as GaInN and AlGaN will result in the formation of dislocation nets confined at the silicon/amorphous region. The resulting nitride containing compound semiconductor material may comprise elements from groups III, IV and V of the periodic table and is defect free.

Although GaN has been grown on SiC substrate in the past, this embodiment of the invention possesses a one step formation of the compliant substrate containing a SiC top surface (capping layer 82) and an amorphous layer (layer 84) on a Si surface (substrate 72). More specifically, this embodiment of the invention uses an intermediate single crystal oxide layer that is amorphosized to form a silicate layer that adsorbs the strain between the layers. Moreover, unlike past use of a SiC substrate, this embodiment of the invention is not limited by wafer size which is usually less than 2 inches in diameter for prior art SiC substrates.

The monolithic integration of nitride containing semiconductor compounds containing group III-V nitrides and silicon devices can be used for high temperature RF applications and optoelectronics. GaN systems have particular use in the photonic industry for the blue/green and UV light sources and detection. High brightness light emitting diodes (LEDs) and lasers may also be formed within the GaN system.

FIGS. 21-23 schematically illustrate, in cross-section, the formation of another embodiment of a device structure in accordance with the invention. This embodiment includes a compliant layer that functions as a transition layer that uses clathrate or Zintl type bonding. More specifically, this embodiment utilizes an intermetallic template layer to reduce the surface energy of the interface between material layers thereby allowing for two dimensional layer by layer growth.

The structure illustrated in FIG. 21 includes a monocrystalline substrate 90, an amorphous intermediate layer 94 and an accommodating buffer layer 92. The amorphous interface layer 94 is formed on the substrate 90 at the interface between the substrate 90 and the accommodating buffer layer 92 as previously described with reference to FIGS. 1 and 2. The amorphous intermediate layer 94 may comprise any of those materials previously described with reference to the amorphous interface layer 28 in FIGS. 1 and 2. The substrate 90 is preferably silicon but may also comprise any of those materials previously described with reference to the substrate 22 in FIGS. 1-3.

A template layer 96 is deposited over the accommodating buffer layer 92 as illustrated in FIG. 22 and preferably comprises a thin layer of Zintl type phase material composed of metals and metalloids having a great deal of ionic character. As in previously described embodiments, the template layer 96 is deposited by way of MBE, CVD, MOCVD, MEE, ALE, PVD, CSD, PLD, or the like to achieve a thickness of one monolayer. The template layer 96 functions as a “soft” layer with non-directional bonding but high crystallinity that absorbs stress build up between layers having lattice mismatch. Materials for the template layer 96 may include, but are not limited to, materials containing Si, Ga, In, and Sb, such as, for example, AlSr₂, (MgCaYb)Ga₂, (Ca,Sr,Eu,Yb) In₂, BaGe₂As, and SrSn₂As₂

A monocrystalline material layer 98 is epitaxially grown over the template layer 96 to achieve the final structure illustrated in FIG. 23. As a specific example, an SrAl₂ layer may be used as the template layer 96 and an appropriate monocrystalline material layer 98 such as a compound semiconductor material GaAs is grown over the SrAl₂. The Al—Ti (from the accommodating buffer layer 92 of layer of Sr_{z}Ba_{1-z}TiO₃ where z ranges from 0 to 1) bond is mostly metallic while the Al—As (from the GaAs layer) bond is weakly covalent. The Sr participates in two distinct types of bonding with part of its electric charge going to the oxygen atoms in the accommodating buffer layer 92 to participate in ionic bonding and the other part of its valence charge being donated to Al in a way that is typically carried out with Zintl phase materials. The amount of the charge transfer depends on the relative electronegativity of elements of the template layer 96 as well as on the interatomic distance. In this example, Al assumes an sp³ hybridization and can readily form bonds with the monocrystalline material layer 98, which in this example, comprises compound semiconductor material GaAs.

The compliant substrate produced by use of the Zintl type template layer 96 used in this embodiment can absorb a large strain without a significant energy cost. In the above example, the bond strength of the Al is adjusted by changing the volume of the SrAl₂ of the template layer 96 thereby making the device tunable for specific applications that include the monolithic integration of III-V and Si devices and the monolithic integration of high-k dielectric materials for CMOS technology.

Clearly, those embodiments specifically describing structures having compound semiconductor portions and Group IV semiconductor portions are meant to illustrate embodiments of the present invention and not limit the present invention. There are a multiplicity of other combinations and other embodiments of the present invention. For example, the present invention includes structures and methods for fabricating material layers that form semiconductor structures, devices and integrated circuits including other layers such as metal and non-metal layers. More specifically, the invention includes structures and methods for forming a compliant substrate that is used in the fabrication of semiconductor structures, devices and integrated circuits and the material layers suitable for fabricating those structures, devices, and integrated circuits. By using embodiments of the present invention, it is now easier to integrate devices that include monocrystalline layers of semiconductor and compound semiconductor materials as well as other material layers that are used to form those devices with other components that work better or are easily and/or inexpensively formed within semiconductor or compound semiconductor materials. This allows a reduction in device size, a decrease in the manufacturing costs, and an increase in both yield and reliability to be achieved.

In accordance with one embodiment of this invention, a monocrystalline semiconductor or compound semiconductor wafer can be used in forming monocrystalline material layers over the wafer. In this manner, the wafer is essentially a “handle” wafer used during the fabrication of semiconductor electrical components within a monocrystalline layer overlying the wafer. Therefore, electrical components can be formed within semiconductor materials over a wafer of at least approximately 200 millimeters in diameter and possibly at least approximately 300 millimeters in diameter.

By the use of this type of substrate, a relatively inexpensive “handle” wafer overcomes the fragile nature of compound semiconductor or other monocrystalline material wafers by placing them over a relatively more durable and easy to fabricate base material. Therefore, an integrated circuit can be formed such that all electrical components, and particularly all active electronic devices, can be formed within or using the monocrystalline material layer even though the substrate itself may include a monocrystalline semiconductor material. Fabrication costs for compound semiconductor devices and other devices employing non-silicon monocrystalline materials are decreased because larger substrates can be processed more economically and more readily compared to the relatively smaller and more fragile conventional substrates.

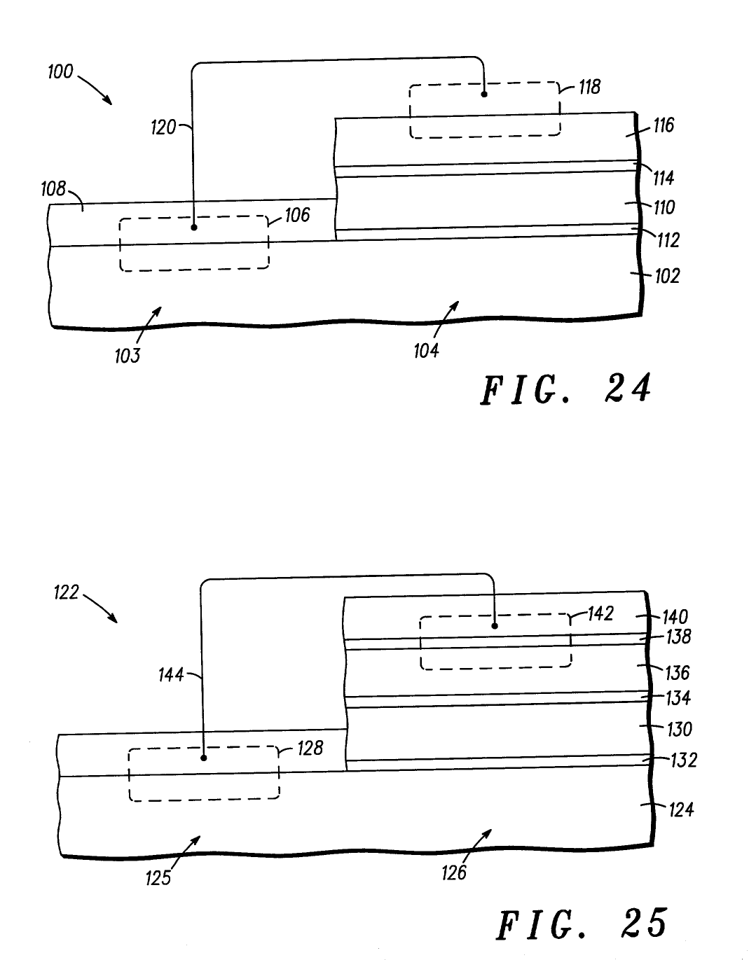

Referring now to FIG. 24, a schematic, cross-sectional view of a device structure 100 in accordance with a further embodiment is shown. The device structure 100 includes a monocrystalline semiconductor substrate 102, which is preferably a monocrystalline silicon wafer. The substrate 102 includes first and second regions, 103 and 104. A first electrical semiconductor component generally indicated by the dashed line 106 is formed, at least partially, in the first region 103. The first component 106 can be a resistor, a capacitor, an active semiconductor component such as a diode or a transistor or an integrated circuit such as a CMOS integrated circuit. For example, the first component 106 can be a CMOS integrated circuit configured to perform digital signal processing or another function for which silicon integrated circuits are well suited. The first component 106 can be formed using conventional semiconductor processing techniques that are well known and widely practiced in the semiconductor industry. A layer of insulating material 108 such as a layer of silicon dioxide or the like may overlie the first component 106.

The insulating material 108 and any other layers that may have been formed or deposited during the processing of the first component 106 in the first region 103 are removed from the surface of the second region 104 to provide a bare silicon surface in that region. As is well known, bare silicon surfaces are highly reactive and a native silicon oxide layer can quickly form on the bare surface. A layer of barium or barium and oxygen is deposited onto the native oxide layer on the surface of the second region 104 and is reacted with the oxidized surface to form a first template layer (not shown).

In accordance with one embodiment, a monocrystalline oxide layer 110 is formed overlying the template layer by a process of MBE. Reactants including barium, titanium and oxygen are deposited onto the template layer to form the monocrystalline oxide layer 110. Initially during the deposition the partial pressure of oxygen is kept near the minimum necessary to fully react with the barium and titanium to form a monocrystalline barium titanate layer. The partial pressure of oxygen is then increased to provide an overpressure of oxygen and to allow oxygen to diffuse through the growing monocrystalline oxide layer 110. The oxygen diffusing through the barium titanate reacts with silicon at the surface of the second region 104 to form an amorphous layer 112 of silicon oxide on the second region 104 and at the interface between the silicon substrate 102 and the monocrystalline oxide layer 110. The monocrystalline oxide layer 110 and the amorphous layer 112 may be subject to an annealing process as described above in connection with FIG. 3 to form a single amorphous accommodating layer.

In accordance with an embodiment, the step of depositing the monocrystalline oxide layer 110 is terminated by depositing a second template layer 114, which can be 1-10 monolayers of titanium, barium, barium and oxygen, or titanium and oxygen. A second monocrystalline layer 116 of a monocrystalline compound semiconductor material is then deposited overlying the second template layer 114 by a process of MBE. The deposition of the second monocrystalline layer 116 is initiated by depositing a layer of arsenic onto the second template layer 114. This step is followed by depositing gallium and arsenic to form the second monocrystalline layer 116 of gallium arsenide. Alternatively, strontium can be substituted for barium in the above example.

In accordance with a further embodiment, a second electrical semiconductor component, generally indicated by dashed line 118 is formed in the second monocrystalline layer 116. The second component 118 can be formed by conventional processing steps used in the fabrication of gallium arsenide or other type III-V compound semiconductor material devices. The second component 118 can be any active or passive component, and preferably is a semiconductor laser, light emitting diode, photodetector, heterojunction bipolar transistor (HBT), high frequency MESFET, or other component that uses and takes advantage of the physical properties of compound semiconductor materials. A metallic conductor schematically indicated by the line 120 can be formed to electrically couple the first component 106 and the second component 118, thus implementing an integrated device that includes at least one component formed in the silicon substrate 102 and one device formed in the monocrystalline compound semiconductor material layer 116. Although the semiconductor structure 100 has been described being formed on a silicon substrate and having a barium (or strontium) titanate layer (layer 110) and a gallium arsenide layer (layer 116), similar devices can be fabricated using other substrates, monocrystalline oxide layers and other compound semiconductor layers as described elsewhere in this disclosure.

FIG. 25 illustrates a semiconductor structure 122 in accordance with a further embodiment. The structure 122 includes a monocrystalline semiconductor substrate 124 such as a monocrystalline silicon wafer that includes a first region 125 and a second region 126. A first electrical component schematically illustrated by the dashed line 128 is formed in the first region 125 using silicon device processing techniques commonly used in the semiconductor industry. Using process steps similar to those described above, a monocrystalline oxide layer 130 and an intermediate amorphous silicon oxide layer 132 are formed overlying the second region 126 of the substrate 124. A template layer 134 and subsequently a monocrystalline semiconductor layer 136 are formed overlying the monocrystalline oxide layer 130. In accordance with a further embodiment, an additional monocrystalline oxide layer 138 is formed overlying the monocrystalline semiconductor layer 136 by process steps similar to those used to form the monocrystalline oxide layer 130, and an additional monocrystalline semiconductor layer 140 is formed overlying the additional oxide layer 138 by process steps similar to those used to form the monocrystalline semiconductor layer 136. In accordance with one embodiment, at least one of the monocrystalline layers 136 and 140 are formed from a compound semiconductor material. The monocrystalline oxide layer 130 and the intermediate amorphous layer 132 may be subject to an annealing process as described above in connection with FIG. 3 to form a single amorphous accommodating layer.

A second semiconductor component generally indicated by dashed line 142 is formed at least partially in the monocrystalline semiconductor layer 136. In accordance with one embodiment, the second component 142 may include a field effect transistor having a gate dielectric formed, in part, by the additional oxide layer 138. In addition, the additional monocrystalline semiconductor layer 140 can be used to implement the gate electrode of that field effect transistor. In accordance with one embodiment, the monocrystalline semiconductor layer 136 is formed from a group III-V compound and the second component 142 is a radio frequency amplifier that takes advantage of the high mobility characteristic of group III-V component materials. In accordance with yet a further embodiment, an electrical interconnection schematically illustrated by the line 144 electrically connects the first and second component 128 and 142. The structure 122 thus integrates components that take advantage of the unique properties of the two monocrystalline semiconductor materials.

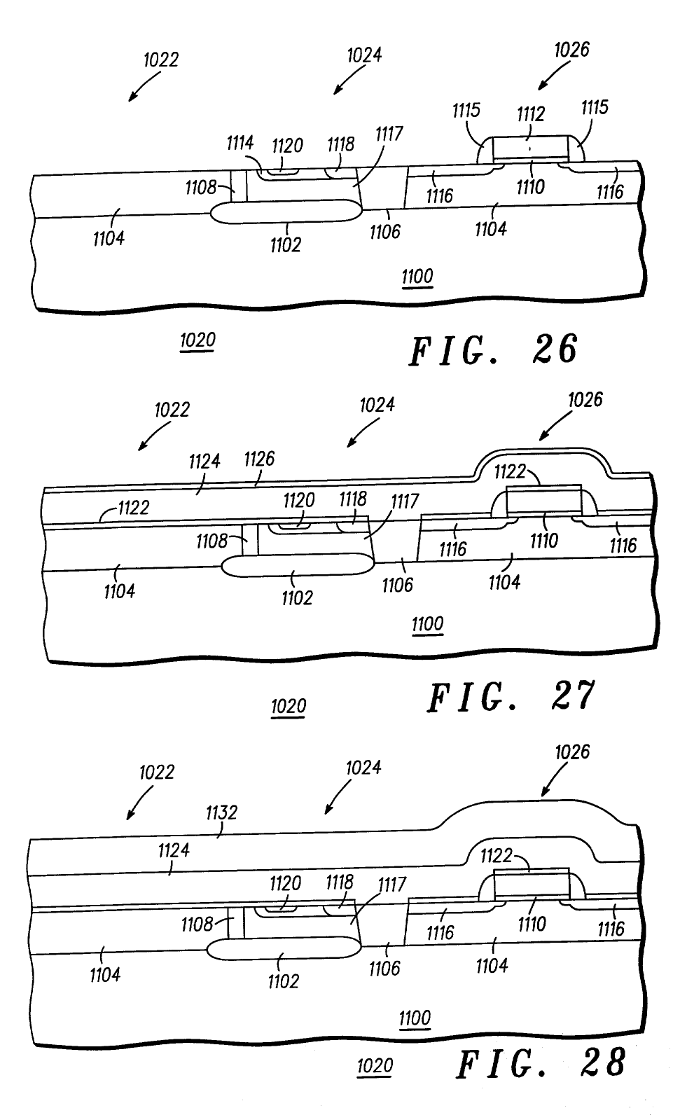

Attention is now directed to a method for forming exemplary portions of illustrative composite semiconductor structures or composite integrated circuits like the semiconductor structures 100 or 122 of FIGS. 24-25. In particular, an illustrative composite semiconductor structure or integrated circuit 1020 shown in FIGS. 26-30 includes a compound semiconductor portion 1022, a bipolar portion 1024, and a MOS portion 1026.

Referring now to FIG. 26, a p-type doped, monocrystalline silicon substrate 1100 is provided having a compound semiconductor portion 1022, a bipolar portion 1024, and an MOS portion 1026. Within the bipolar portion 1024, the substrate 1100 is doped to form an N⁺ buried region 1102. A lightly p-type doped epitaxial monocrystalline silicon layer 1104 is then formed over the N+buried region 1102 and the substrate 1100. A doping step is then performed to create a lightly n-type doped drift region 1117 above the N⁺ buried region 1102. The doping step converts the dopant type of the lightly p-type epitaxial layer 1104 within a section of the bipolar region 1024 to a lightly n-type monocrystalline silicon region. A field isolation region 1106 is then formed between the bipolar portion 1024 and the MOS portion 1026. A gate dielectric layer 1110 is formed over a portion of the epitaxial layer 1104 within the MOS portion 1026, and a gate electrode 1112 is then formed over the gate dielectric layer 1110. Sidewall spacers 1115 are formed along vertical sides of the gate electrode 1112 and the gate dielectric layer 1110.

A p-type dopant is introduced into the drift region 1117 to form an active or intrinsic base region 1114. An n-type, deep collector region 1108 is then formed within the bipolar portion 1024 to allow electrical connection to the buried region 1102. Selective n-type doping is performed to form N⁺ doped regions 1116 and an emitter region 1120. The N⁺ doped regions 1116 are formed within silicon layer 1104 along adjacent sides of the gate electrode 1112 and are source, drain, or source/drain regions for the MOS transistor. The N⁺ doped regions 1116 and the emitter region 1120 have a doping concentration of at least 1E19 atoms per cubic centimeter to allow ohmic contacts to be formed. A p-type doped region is formed to create an inactive or extrinsic base region 1118 which is a P⁺ doped region having a doping concentration of at least 1E19 atoms per cubic centimeter.

In the embodiment described, several processing steps are performed that are not specifically illustrated or further described, such as the formation of well regions, threshold adjusting implants, channel punch through prevention implants, field punch through prevention implants, as well as a variety of masking layers. The formation of the device up to this point in the process is performed using conventional steps. As illustrated, a standard N-channel MOS transistor has been formed within the MOS portion 1026, and a vertical NPN bipolar transistor has been formed within the bipolar portion 1024. Up to this point, no circuitry has been formed within the compound semiconductor portion 1022.

All of the layers that have been formed during the processing of the bipolar and MOS portions 1024 and 1026 of the integrated circuit are now removed from the surface of the compound semiconductor portion 1022. A bare silicon surface is thus provided for the subsequent processing of the compound semiconductor portion 1022, for example in the manner set forth above.

An accommodating buffer layer 1124 is then formed over the substrate 1100 as illustrated in FIG. 27. The accommodating buffer layer 1124 forms as a monocrystalline layer over the properly prepared (i.e., having the appropriate template layer) bare silicon surface of the compound semiconductor portion 1022. The portion of the accommodating buffer layer 1124 that forms over the bipolar and MOS portions 1024 and 1026, however, may be polycrystalline or amorphous because it is formed over a material that is not monocrystalline, and therefore, does not nucleate monocrystalline growth. The accommodating buffer layer 1124 typically is a monocrystalline metal oxide or nitride layer and typically has a thickness in a range of approximately 2-100 nanometers. In one particular embodiment, the accommodating buffer layer 1124 is approximately 5-15 nm thick. During the formation of the accommodating buffer layer 1124, an amorphous intermediate layer 1122 is formed along the uppermost silicon surfaces of the integrated circuit 1020. This amorphous intermediate layer 1122 typically includes an oxide of silicon and has a thickness of approximately 1-5 nm. In one particular embodiment, the thickness is approximately 2 nm. Following the formation of the accommodating buffer layer 1124 and the amorphous intermediate layer 1122, a template layer 1126 is formed that has a thickness of approximately one to ten monolayers of a material. In one particular embodiment, the material of the template layer 1126 includes titanium-arsenic, strontium-oxygen-arsenic, or other similar materials as previously described with respect to FIGS. 1-3. The amorphous intermediate layer 1122 and the accommodating buffer layer 1124 may be subject to an annealing process as described above in connection with FIG. 3 to form a single amorphous accommodating layer.

Referring now to FIG. 28, a monocrystalline compound semiconductor layer 1132 is epitaxially grown overlying the monocrystalline portions of the accommodating buffer layer 1124 (or over the amorphous accommodating layer if the annealing process described above has been carried out). The portion of the compound semiconductor layer 1132 that is grown over portions of the accommodating buffer layer 1124 that are not monocrystalline may be polycrystalline or amorphous. The monocrystalline compound semiconductor layer 1132 can be formed by a number of methods and typically includes a material such as gallium arsenide, aluminum gallium arsenide, indium phosphide, or other compound semiconductor materials as previously mentioned. The thickness of the compound semiconductor layer 1132 is in a range of approximately 1-5000 nm, and more preferably 100-1000 nm. In this particular embodiment, each of the elements within the template layer 1126 is also present in the accommodating buffer layer 1124, the monocrystalline compound semiconductor material 1132, or both. Therefore, the delineation between the template layer 1126 and its two immediately adjacent layers disappears during processing. Therefore, when a transmission electron microscopy (TEM) photograph is taken, an interface between the accommodating buffer layer 1124 and the monocrystalline compound semiconductor layer 1132 is seen.

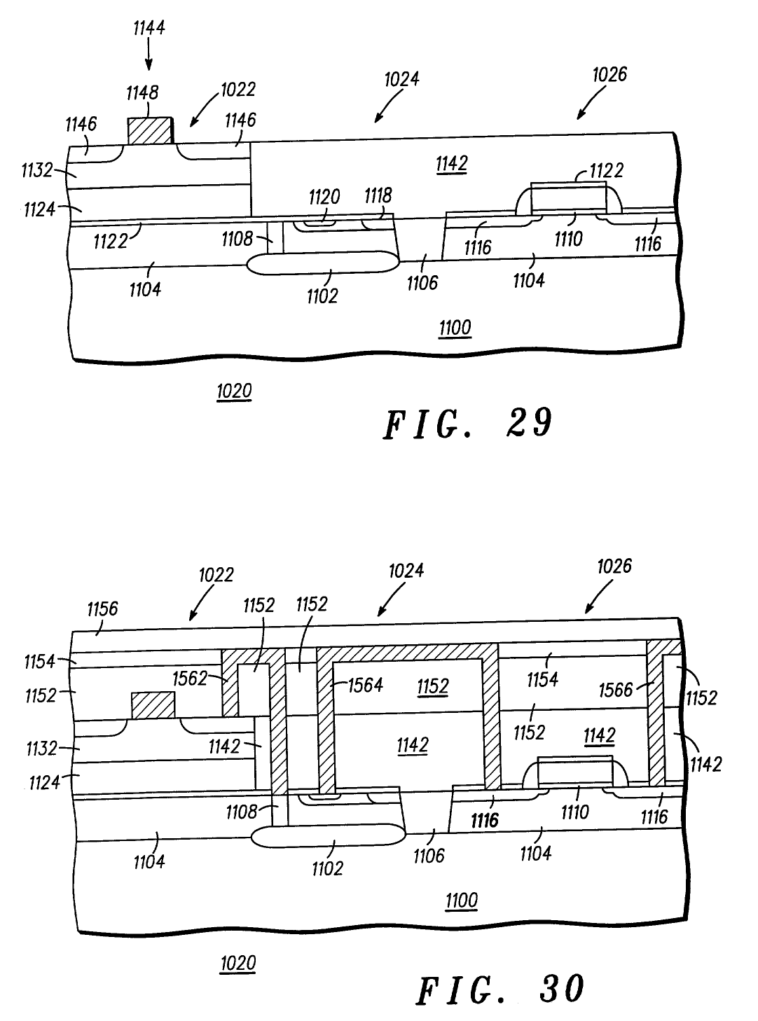

At this point in time, sections of the compound semiconductor layer 1132 and the accommodating buffer layer 1124 (or of the amorphous accommodating layer if the annealing process described above has been carried out) are removed from portions overlying the bipolar portion 1024 and the MOS portion 1026 as shown in FIG. 29. After the sections are removed, an insulating layer 1142 is formed over the substrate 1100. The insulating layer 1142 can include a number of materials such as oxides, nitrides, oxynitrides, low-k dielectrics, or the like. As used herein, low-k refers to materials having a dielectric constant no higher than approximately 3.5. After the insulating layer 1142 has been deposited, portions of the insulating layer 1142 that overlie the monocrystalline compound semiconductor layer 1132 are removed such as by polishing.

A transistor 1144 is then formed within the monocrystalline compound semiconductor portion 1022 of the substrate 1100. A gate electrode 1148 is formed on the monocrystalline compound semiconductor layer 1132. Doped regions 1146 are then formed within the monocrystalline compound semiconductor layer 1132. In this embodiment, the transistor 1144 is a metal-semiconductor field-effect transistor (MESFET). If the MESFET is an n-type MESFET, the doped regions 1146 and the monocrystalline compound semiconductor layer 1132 are also n-type doped. If a p-type MESFET is formed, then the doped regions 1146 and the monocrystalline compound semiconductor layer 1132 have just the opposite doping type. The heavier doped (N⁺) regions 1146 allow ohmic contacts to be made to the monocrystalline compound semiconductor layer 1132. At this point in time, the active devices within the integrated circuit have been formed. This particular embodiment includes an n-type MESFET, a vertical NPN bipolar transistor, and a planar n-channel MOS transistor. Many other types of transistors, including P-channel MOS transistors, p-type vertical bipolar transistors, p-type MESFETs, and combinations of vertical and planar transistors, can be used. Also, other electrical components, such as resistors, capacitors, diodes, and the like, may be formed in one or more of the compound semiconductor,, bipolar, and MOS portions 1022, 1024, and 1026.

Processing continues to form a substantially completed integrated circuit 1020 as illustrated in FIG. 30. An insulating layer 1152 is formed over the substrate 1100. The insulating layer 1152 may include an etch-stop or polish-stop region that is not illustrated in FIG. 30. A second insulating layer 1154 is then formed over the first insulating layer 1152. Portions of the first and second insulating layers 1152 and 1154, insulating layer 1142, accommodating buffer layer 1124, and amorphous intermediate layer 1122 are removed to define contact openings where the devices are to be interconnected. Interconnect trenches are formed within the second insulating layer 1152 to provide lateral connections between the contacts. As illustrated in FIG. 30, an interconnect 1562 connects a source or drain region of the n-type MESFET within the compound semiconductor portion 1022 to the deep collector region 1108 of the NPN transistor within the bipolar portion 1024. The emitter region 1120 of the NPN transistor is connected to one of the doped regions 1116 of the n-channel MOS transistor within the MOS portion 1026. The other doped region 1116 is electrically connected to other portions of the integrated circuit 1020 that are not shown.

A passivation layer 1156 is formed over the interconnects 1562, 1564 and 1566 and the second insulating layer 1154. Other electrical connections are made to the transistors as illustrated as well as to other electrical or electronic components within the integrated circuit 1020 but are not illustrated. Further, additional insulating layers and interconnects may be formed as necessary to form the proper interconnections between the various components within the integrated circuit 1020.

As can be seen from the previous embodiment, active devices for both compound semiconductor and Group IV semiconductor materials can be integrated into a single integrated circuit. Because there is some difficulty in incorporating both bipolar transistors and MOS transistors within the same integrated circuit, it may be possible to move some of the components within the bipolar portion 1024 into the compound semiconductor portion 1022 or the MOS portion 1026. This would eliminate the requirement of special fabricating steps solely used for making a bipolar transistor. Therefore, there would only be a compound semiconductor portion, and a MOS portion to the integrated circuit.

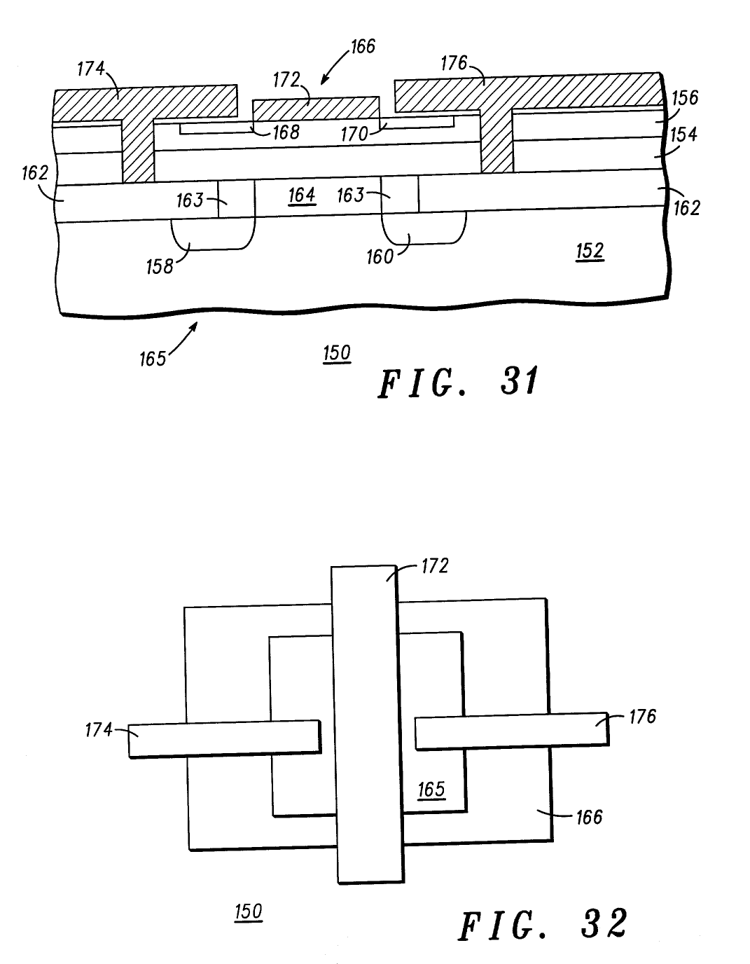

Referring now to FIG. 31, a schematic, cross-sectional view of a portion of a semiconductor device structure 150 in accordance with an embodiment of the invention is shown. The semiconductor device structure 150 comprises a GaAs device, such as a GaAs Field-Effect-Transistor (FET) 166 stacked on top of a MOS device, such as a transistor or MOSFET 165.

More particularly, the semiconductor structure 150 includes a monocrystalline substrate 152, an accommodating buffer layer 154 and a monocrystalline material layer 156, which in this embodiment is GaAs. The substrate 152 is a monocrystalline semiconductor or compound semiconductor wafer, preferably of large diameter, of, for example, a material from Group IV of the periodic table, and preferably a material from Group IVB. Preferably the substrate 152 is a wafer containing silicon or germanium, and most preferably is a high quality monocrystalline silicon wafer as used in the semiconductor industry.

The accommodating buffer layer 154 may be formed by annealing a monocrystalline material and an amorphous material grown on the substrate (not shown), as described above with reference to FIG. 3. In this embodiment, the accommodating buffer layer 154 is preferably an SrTiO₃ (STO) or BaTiO₃ (BTO) material layer and has a thickness of about 0.5 um.

Although in this embodiment, the monocrystalline material layer 156 is preferably GaAs, the monocrystalline material layer 156 could comprise a compound semiconductor selected, as needed for a particular semiconductor structure, from any of the Group IIIA and VA elements (III-V semiconductor compounds), mixed III-V compounds, Group II(A or B) and VIA elements (II-VI semiconductor compounds), and mixed II-VI compounds, or other semiconductor materials, metals, or non-metal materials that are used in the formation of semiconductor structures, devices and/or integrated circuits.

The structure 150 may also include a template layer (not shown) between the accommodating buffer layer 154 and the monocrystalline material layer 156. As previously discussed, the template layer helps to initiate the growth of the monocrystalline material layer 156 on the accommodating buffer layer 154.

In order to form the MOS transistor 165, the substrate 152 includes a source region 158 and a drain region 160. As will be understood by those of ordinary skill in the art, if the substrate is p-type, then the source and drain regions are n-type, and a channel connects the source and drain regions.

A conductive layer 162 is positioned between the substrate 152 and the buffer layer 154. The conductive layer 162 is formed of a highly conductive material or materials, such as LSCO (Lanthium Strontium Copper Oxide), Silicon Rich Oxides (SRO), metal oxides and/or metal. In the preferred embodiment, the conductive layer 162 has a thickness of between about 0.1 um to about 1.0 um. A gate 164 of the transistor 165 is formed overlying the substrate 152 and between the source region 158 and the drain region 160. Preferably, the gate is formed of poly-silicon (poly). A contact spacing 163 is provided on each side of the gate 164.

The GaAs FET 166 is formed on top of the transistor 165 after the completion of the processing of the silicon device. The GaAs FET 166 includes a source region 168 and a drain region 170 formed in the GaAs layer 156, and a gate 172 overlying the GaAs layer 156 between the source region 168 and the drain region 170, as shown in FIG. 31. In this embodiment, the gate 172 is preferably a metal, such as TiSi₂, which has a work function of about 4.245 eV. However, as will be understood by those of skill in the art, the gate 172 may be formed of other conductive materials, such as tungsten nitride (WNx). The GaAs FET 166 preferably has a thickness of about 2000 Angstroms.

A first metal interconnect 174 connects the source 158 of the transistor 165 and the source 168 of the GaAs FET 166, by way of the LSCO interconnect layer 162 and a second metal interconnect 176 connects the drain 160 of the transistor 165 and the drain 170 of the GaAs FET 166, by way of the LSCO interconnect layer 162. The first and second metal interconnects 174 and 176 may be formed of any conductive material, such as copper, aluminum, nickel, gold, platinum, etc., and preferably are formed of titanium/gold or titanium/platinum/gold.

FIG. 32 is a top plan view of the device structure 150, showing the interconnections between the transistor 165 and the GaAs FET 166. By stacking the GaAs FET 166 on top of the transistor 165, the structure 150 provides a GaAs FET with a larger effective gate width than a conventional GaAs FET, which enhances the transconductance of the device structure 150.

As will be apparent to those of ordinary skill in the art, the stacked Si/GaAs GET of the present invention can be extended to other circuits that benefit from stacked Si and GaAs to save area, reduce parasitics and optimize performance, such as, for example, a GaAs pull-up and a Si pull-down inverter.

In the foregoing specification, the invention has been described with reference to specific embodiments. However, one of ordinary skill in the art will appreciate that various modifications and changes can be made without departing from the scope of the present invention as set forth in the claims below. Benefits, other advantages, and solutions to problems have been described above with regard to specific embodiments. However, the benefits, advantages, solutions to problems, and any element(s) that may cause any benefit, advantage, or solution to occur or become more pronounced are not to be construed as a critical, required, or essential features or elements of any or all the claims. Accordingly, the specification and figures are to be regarded in an illustrative rather than a restrictive sense, and all such modifications are intended to be included within the scope of present invention.

We claim:

1. A semiconductor device, comprising:
a MOS device including a silicon substrate;
an accommodating buffer layer overlying the MOS device;
a GaAs device formed over the MOS device and the accommodating buffer layer, the GaAs device including a GaAs material layer; and
interconnects connecting the GaAs device and the MOS device, wherein the accommodating buffer layer minimizes lattice mismatches between the silicon substrate and the GaAs material layer.

2. The semiconductor device of claim 1, wherein the accommodating buffer layer is formed by annealing a monocrystalline material and an amorphous material.

3. The semiconductor device of claim 1, wherein the accommodating buffer layer is formed of STO.

4. The semiconductor device of claim 1, wherein the accommodating buffer layer is formed of BTO.

5. The semiconductor device of claim 1, wherein the MOS device comprises a MOSFET.

6. The semiconductor device of claim 5, wherein the GaAs device comprises a GaAs FET.

7. The semiconductor device of claim 6, wherein the interconnects comprise:
a conductive layer overlying the silicon substrate and electrically coupled to the MOSFET; and
a metal inter connect electrically connected to the GaAs FET and extending from the GaAs FET to the conductive layer overlying the silicon substrate, such that the MOSFET is electrically connected to the GaAs FET by way of the conductive layer and the metal interconnect.

8. The semiconductor device of claim 7, wherein the conductive layer comprises LSCO.

9. The semiconductor device of claim 7, wherein the conductive layer comprises SRO.

10. The semiconductor device of claim 1, wherein the GaAs device comprises a pull-up inverter and the MOS device comprises a pull-down inverter.

11. A semiconductor device structure, comprising:
a monocrystalline substrate having a source region and a drain region;
a first gate formed over a first part of a surface of the substrate, said first part being between the source region and the drain region;
a conductive layer overlying a remaining part of the substrate surface, wherein a contact opening separates the conductive layer from the first gate, the substrate, source region, drain region and first gate defining an MOS device;
an accommodating buffer layer overlying the substrate;
a monocrystalline GaAs material layer overlying the accommodating buffer layer, wherein the accommodating buffer layer minimizes lattice mismatches between the substrate and the GaAs material layer, and wherein the GaAs material layer includes a source region and a drain region;
a second gate formed over a first part of a surface of the GaAs material layer, said first part being between the source region and the drain region of the GaAs material layer, wherein the GaAs material layer, the GaAs source region, the GaAs drain region and the second gate define a GaAs device; and
a metal interconnect electrically connecting the GaAs source and drain regions to the substrate source and drain regions by way of the conductive layer such that the MOS device is connected to the GaAs device.

12. The device structure of claim 11, wherein the first gate comprises poly.

13. The device structure of claim 12, wherein the conductive layer comprises a highly conductive material such as LSCO and SRO.

14. The semiconductor device of claim 11, wherein the accommodating buffer layer is formed by annealing a monocrystalline material and an amorphous material.

15. The semiconductor device of claim 11, wherein the accommodating buffer layer is formed of STO.

16. The semiconductor device of claim 11, wherein the accommodating buffer layer is formed of BTO.

17. The semiconductor device of claim 11, wherein the metal interconnect comprises:
a first metal interconnect extending from above the GaAs material layer to at least a portion of the conductive layer and electrically connecting the GaAs source region with the substrate source region by way of the conductive layer; and
a second metal interconnect extending from above the GaAs material layer to at least a portion of the conductive layer and electrically connecting the GaAs drain region with the substrate drain region by way of the conductive layer.

18. A method of fabricating a semiconductor device structure, comprising the steps of:
providing a monocrystalline silicon substrate;
forming a source region and a drain region in the substrate;
forming a MOS device by forming a first gate overlying a portion of a surface of the substrate between the substrate source region and the substrate drain region;
forming an accommodating buffer layer overlying the substrate by annealing a monocrystalline material and an amorphous material on the substrate;
epitaxially forming a monocrystalline GaAs layer overlying the accommodating buffer layer;
forming a source region and a drain region in the GaAs layer;
forming a GaAs device over the MOS device and the accommodating buffer layer by forming a second gate over the GaAs layer and between the GaAs source and drain regions; and
forming interconnects that extend from the GaAs source and drain regions to the MOS source and drain regions, thereby connecting the GaAs device and the MOS device.
